(19) United States
(12) Patent Application Publication
(10) Pub. No.: US 2023/0374330 A1
(43) Pub. Date: Nov. 23, 2023

(54) CONDUCTIVE ELECTRONIC TEXTILES

(71) Applicant: Nanyang Technological University, Singapore (SG)

(72) Inventors: Jian LYU, Singapore (SG); Gurunathan THANGAVEL, Singapore (SG); Pooi See LEE, Singapore (SG)

(21) Appl. No.: 18/252,447

(22) PCT Filed: Jan. 26, 2021
(86) PCT No.: PCT/SG2022/050038

§ 371 Date: May 10, 2023

(30) Foreign Application Priority Data
Jan. 26, 2021 (SG) 10202100851

(51) Int. Cl. C09D 11/52; C08G 18/32; C08G 18/10; C08G 18/75; C08G 18/67; C09D 11/102; H01M 10/056; H01M 4/66

(52) U.S. Cl. CPC C09D 11/52; C08G 18/3206; C08G 18/10; C08G 18/755; C08G 18/672; C09D 11/102; H01M 10/056; H01M 4/661; C08K 2003/0806

(57) ABSTRACT

Disclosed herein are a flexible textile-based silver electrode and a sweat-activated battery. Also disclosed herein is a method of making the flexible textile-based silver electrode by providing a composite material comprising a flexible textile substrate and a polymeric silver electrode wire, and bringing the composite material into contact with an aqueous solution comprising a non-toxic chloride salt and an organic acid for a period of time, wherein the electrode wire comprising an elastomeric material and silver flakes homogeneously distributed throughout the elastomeric material.

### FIELD OF INVENTION

The current invention relates to conductive electronic textiles, their formation and uses.

### BACKGROUND

The listing or discussion of a prior-published document in this specification should not necessarily be taken as an acknowledgement that the document is part of the state of the art or is common general knowledge.

Electronic textile (E-textile) is a kind of smart textile integrated with sensors, transducers, energy devices, and wireless communications. It provides massive opportunities for healthcare and environment monitoring, human-machine interface, and defense. Human has a long history of using textile as clothing for body protection and fashion, and emerging flexible electronics impart new functions to traditional textiles. Textiles are in direct contact with human skin in daily wearing and thus, can serve both as substrates for the fabrications of emerged flexible devices and the platform for traditional rigid silicon circuits (Niu, S. et al., Nat. Electron. 2019, 2, 361-368; and Tian, X. et al., Nat. Electron. 2019, 2, 243-251). For E-textile, the most important part is the highly flexible and conductive electrodes and interconnections that can be durable to mechanical deformation, especially stretching, coming from the wearer's daily activities. Various technologies have been invented to pattern flexible conductive electrodes on textiles, from functionalizing the original fabrics to directly coating conductive materials on textiles (U.S. Pat. No. 8,945,328 B2; and Wang, L. et al., Adv. Mater. 2020, 32, 1901971).

Printing technologies, including screen printing, 3-D printing, inkjet printing, are highly compatible with textile technologies due to their low-temperature curing, ease of pattern design, scalable production, customer-design capability, and less material waste. The use of printing to produce conductive electrodes and interconnects on textiles has been widely adopted in wearable sensors, wireless communications, energy devices. The key components in wearable devices are stretchable ink, flexible and soft functional electrodes, and conductive wiring.

Silver (Ag)-based stretchable inks that include the elastomer at a high proportion as the binder, and Ag particles as the conductive fillers have been widely applied as inks for textile-based wiring or interconnect due to their superior conductivity, high stretchability and good stability compared with other inks, such as carbon inks and copper inks. The Ag-based inks can be printed directly on textiles or through a polymeric interlayer. During the stretching, the binder will prevent the separation of Ag conductive fillers and maintain the conductive percolation. However, most of the existing Ag-based textile still suffer from low initial resistance when compared with bulk Ag electrodes, and significant resistance increase during stretching. The high initial resistance comes from the surfactant on the surface of Ag flakes and a high proportion of elastomeric binder. The significant resistance increase during stretching cycling results from the separation of Ag flakes from adjacent flakes that will slide to accommodate the external strain.

Some methods have been invented to solve these problems. Takao Someya used low vapor pressure and high boiling point solvent to enable the deep permeation of ink into the textile and thus, the ink will cover each fiber bundle instead of filling up the vacancy (Jin, H. et al., Adv. Mater. 2017, 29, 1605848). Then, the wave structure of the textile instead of the Ag flakes ink was used to deform along with the strain. This method is limited by the use of a high boiling point solvent which means that the spreading of the ink after printing is very severe and thus, high precision is hard to reach. Also, the hot-press process (160° C.) in this method may induce the degradation of the textile substrate, considering most commodity textile degrades at temperatures between 125 and 180° C. Chung and coworkers used Ag powders to replace Ag flakes to improve the penetration of the ink into the textile (La, T.-G. et al., Adv. Healthc. Mater. 2018, 7, 1801033). However, the efforts only involve the enhancement of permeation depth and still can't reach both low initial resistance and high conductivity during cycling stretching.

The interaction between wearable electrodes and body motion, body heat, or biofluids can be applied to realize in-vivo physiological signal sensing (Kim, J. et al., Nat. Biotechnol. 2019, 37, 389-406), human-machine interactions (Wang, J. et al., Mater. Today 2018, 21, 508-526), drug delivery (Jin, H. et al., Adv. Mater. 2017, 29, 1605848), or bioenergy harvesting (La, T.-G. et al., Adv. Healthc. Mater. 2018, 7, 1801033; and Sun, S. et al., J. Mater. Sci. Mater. Electron. 2016, 27, 4363-4371). The materials design and interaction mechanism of wearable devices with the human body are vital for the successful realization of specific applications, which would open up a new era for the design of wearable devices. However, most of the research focuses on the versatile design of the functional electrodes, and the effect of biofluids on the conductive wiring has rarely been studied.

Human sweat is one of the most available biofluids that have been applied in the fabrication of non-invasive biosensors for continuous monitoring of physiological information (Kim, J. et al., Acc. Chem. Res. 2018, 51, 2820-2828). Also, biocompatible and safe wearable biofuel cells (Lv, J. et al., Energy Environ. Sci. 2018, 11, 3431-3442), supercapacitors (Manjakkal, L. et al., Adv. Mater. 2020, 32, 1907254), and batteries (Bandodkar, A. J. et al., Nat. Electron. 2020, 3, 554-562) that use human sweat as electrolytes have been fabricated as power sources for wearable sensors. Sweat containing lactic acid and glucose, and ions (such as Na⁺ and Cl⁻) enables the realization of wearable biofuel cells, supercapacitors, and batteries to function as well as their regular counterparts. Conductive and stretchable wiring plays a key role in the design and fabrication of stretchable devices. However, the effect of sweat on the Ag electrodes has always been considered a deteriorating effect for electrode's conductivity because of the enhanced corrosion behavior of bulk metals in the presence of saline solution (Zhou, W. et al., ACS Nano 2020, 14, 5798-5805).

Therefore, there exists a need to discover new wearable textile electronics that can overcome the limitations mentioned above.

### SUMMARY OF INVENTION

1. A flexible textile-based silver electrode, comprising:
a flexible textile substrate having a surface; and
a polymeric silver electrode wire attached to the surface of the flexible textile substrate, the electrode wire comprising:
an elastomeric material; and
silver flakes homogeneously distributed throughout the elastomeric material,
   wherein:
the fraction of Ag⁰ in the silver flakes is from 89 to 95% relative to Ag⁺; and
the hysteresis (ΔR/R₀) of the flexible textile-based silver electrode following 100 cycles of being elongated by 50% of its original dimension is from 1.1 to 2, such as from 1.3 to 1.9, such as about 1.86.

2. The flexible textile-based silver electrode according to claim 1, wherein the elastomeric material is selected from one or more of a silicone rubber, a styrenic elastomer, and a polyurethane-based elastomer.

3. The flexible textile-based silver electrode according to claim 2, wherein the elastomeric material is a hydrophilic polyurethane acrylate elastomer.

4. The flexible textile-based silver electrode according to claim 2 or claim 3, wherein the elastomeric material is cured.

5. The flexible textile-based silver electrode according to any one of claims 2 to 4, wherein the uncured elastomeric material has a formula I:

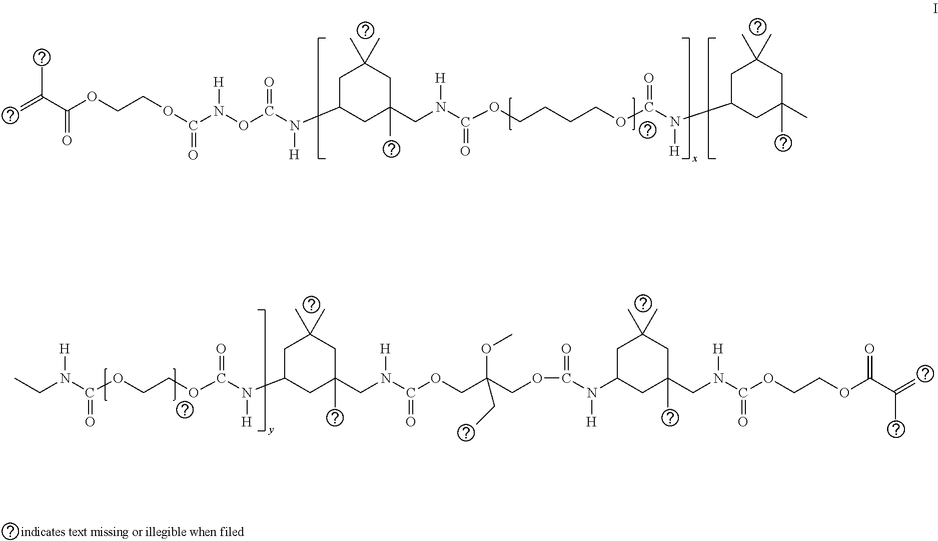

where n, x and y represent repeating units, and the cured elastomeric material, when present, is the acrylate-polymerised version thereof.

6. The flexible textile-based silver electrode according to any one of the preceding claims, wherein one or more of the following apply:
(ci) the weight to weight ratio of the silver flakes to elastomeric material is from 1:0.1 to 0.1:1, such as from 1:0.5 to 0.5:1 such as about 1:0.75;
(cii) the resistance of the flexible textile-based silver electrode in a relaxed state is from 0.1 to 1.5Ω; and
(ciii) the resistance of the flexible textile-based silver electrode does not exceed 7Ω when the flexible textile-based silver electrode is subjected to 500 cycles of being elongated by 30% of its original dimension in any direction.

7. The flexible textile-based silver electrode according to any one of the preceding claims, wherein one or more of the following apply:
(ai) a surface of the polymeric silver electrode wire that is not in direct contact with the textile substrate is coated by a non-silver containing elastomeric material;
(aii) flexible textile substrate comprises a plurality of bundles of yarn on the surface of the textile substrate, where at the plurality of bundles of yarn in contact with the polymeric silver electrode wire extend partly into the polymeric silver electrode wire; and
(aiii) the elastomeric material has a water contact angle of from 10 to 25°, such as from 15 to 16°, after contact with a water droplet for 80 minutes.

8. A sweat-activated battery comprising:
a textile substrate;
a cathode comprising a cathode sweat-activated active material and a first elastomeric material on the textile substrate;
an anode comprising a sweat-activated active material and a second elastomeric material on the textile substrate; and
a current collector formed from a polymeric silver electrode wire attached to the surface of the flexible textile substrate, the electrode wire comprising:
   a third elastomeric material; and
   silver flakes homogeneously distributed throughout the third elastomeric material, wherein
a current is produced by the battery when the battery is placed into an environment including an aqueous composition comprising an inorganic chloride salt and an organic acid.

9. The battery according to claim 8, wherein the anode sweat-activated active material is selected from one or more of zinc powder (particles/flakes) and carbon particles (e.g. carbon black, graphite, carbon nanotube and graphene), optionally wherein the anode sweat-activated active material is a combination of zinc flakes and carbon black in a weight to weight ratio of from 80:20 to 95:5, such as 90:10.

10. The battery according to claim 8 or claim 9, wherein the weight to weight ratio of the anode sweat-activated active material to elastomeric material is from 1:1 to 1:3, such as 1:2.

11. The battery according to any one of claims 8 to 10, wherein the cathode sweat-activated active material is selected from one or more of Ag₂O powder and carbon (e.g. carbon black, graphite, carbon nanotube and graphene), optionally wherein the cathode sweat-activated active material is a combination of Ag₂O powder and carbon black in a weight to weight ratio of from 85:15 to 98:2, such as 95:5.

12. The battery according to any one of claims 8 to 11, wherein the weight to weight ratio of the cathode sweat-activated active material to elastomeric material is from 1:1 to 1:1.5, such as 1:1.2.

13. The battery according to any one of claims 8 to 12, wherein each of the first to third elastomeric materials are independently selected from one or more of a silicone rubber, a styrenic elastomer, and a polyurethane-based elastomer.

14. The battery according to claim 13, wherein each of the first to third elastomeric materials are a hydrophilic polyurethane acrylate elastomer.

15. The battery according to claim 13 or claim 14, wherein each of the first to third the elastomeric materials are cured.

16. The battery according to any one of claims 13 to 15, wherein for each of the first to third elastomeric materials the uncured elastomeric material has a formula I:

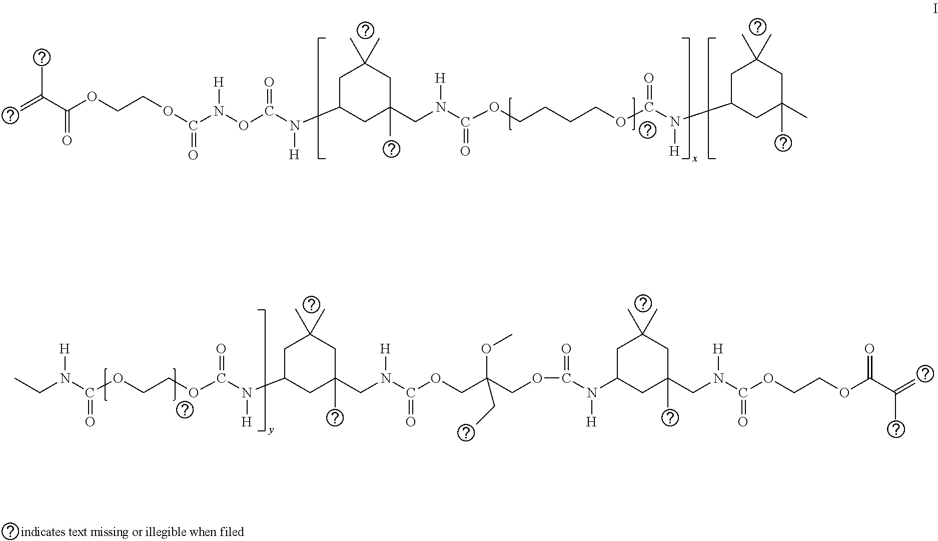

where n, x and y represent repeating units, and the cured elastomeric material, when present, is the acrylate-polymerised version thereof.

17. The battery according to any one of claims 8 to 16, wherein the weight to weight ratio of the silver flakes to the third elastomeric material is from 1:0.1 to 0.1:1, such as from 1:0.5 to 0.5:1 such as about 1:0.75.

18. The battery according to any one of claims 8 to 17, wherein one or more of the following apply:
(ai) a surface of the polymeric silver electrode wire that is not in direct contact with the textile substrate is coated by a non-silver containing elastomeric material;
(aii) flexible textile substrate comprises a plurality of bundles of yarn on the surface of the textile substrate, where at the plurality of bundles of yarn in contact with the polymeric silver electrode wire extend partly into the polymeric silver electrode wire; and
(aiii) the elastomeric material has a water contact angle of from 10 to 25°, such as from 15 to 16°, after contact with a water droplet for 80 minutes.

19. A device comprising:
one or more sweat-activated batteries according to any one of claims 8 to 18; and
a capacitor.

20. A method of making a flexible textile-based silver electrode as described in any one of claims 1 to 7, comprising the steps of:
(a) providing a composite material comprising:
   a flexible textile substrate having a surface; and
   a polymeric silver electrode wire attached to the surface of the flexible textile substrate, the electrode wire comprising:
   an elastomeric material; and
   silver flakes homogeneously distributed throughout the elastomeric material; and
(b) bringing the composite material into contact with an aqueous solution comprising a non-toxic chloride salt and an organic acid for a period of time to form the flexible textile-based silver electrode.

21. The method according to claim 20, wherein the pH of the aqueous solution is from 2.5 to 4.0.

22. The method according to claim 20 or claim 21, wherein step (b) of claim 20 is conducted in a washing machine.

23. The method according to any one of claims 20 to 22, wherein the aqueous solution comprises from 0.1 to 1 wt/v %, such as from 0.4 to 0.6 wt/v %, such as about 0.5 wt/v % of an inorganic chloride salt and from 0.05 to 0.5 wt/v %, such as from 0.075 to 0.125 wt/v %, such as about 0.1 wt/v % of an organic acid.

24. The method according to any one of claims 20 to 23, wherein one or both of the following apply:
(i) the non-toxic chloride salt is selected from one or more of the group consisting of CaCl₂), MgCl₂ and, more particularly, NaCl and KCl; and
(ii) the organic acid is selected from one or more of the group consisting of citric acid, acetic acid, tartaric acid, malic acid and, more particularly, lactic acid.

25. The method according to any one of claims 20 to 24, wherein the period of time in step (b) of claim 20 is at least 30 seconds to 24 hours.

26. The method according to any one of claims 20 to 25, wherein the flexible textile substrate is loaded with an organic acid, optionally wherein the organic acid is selected from one or more of the group consisting of citric acid, acetic acid, tartaric acid, malic acid and, more particularly, lactic acid.

### DRAWINGS

FIG. 1 depicts the design and synthesis of highly stretchable and transparent ultraviolet (UV) curable hydrophilic poly(urethane-acrylate) elastomers (HPUAs) via acrylate photopolymerization under UV irradiation.

FIG. 2 depicts the synthesis of the isocyanate-terminated NCO-PTHF-NCO prepolymer.

FIG. 3 depicts the hydrophilic HPUA elastomer design and characterization. (A) Chemical structure of multifunctional hydrophilic HPUA elastomer; (B) Temperature dependence of storage modulus (E′) and dissipation factor (tan δ) of HPUA-1, HPUA-2, and HPUA-3 measured by dynamic mechanical analysis under a N₂ atmosphere, at a heating rate of 3° C./min and a frequency of 1 Hz; (C) ultraviolet-visible (UV-Vis) spectra of HPUAs with different wt % of 2-hydroxyethyl methacrylate (HEMA); (D) and (E) Compared images and the dynamic contact angles of artificial a sweat droplet on the HPUA and polystyrene-block-poly(ethylene butylene)-block-polystyrene (SEBS) glass substrate, respectively; (F) Digital photograph of the highly stretchable HPUA film. Scale bar: 3 cm; (G) Schematic representation of the reversible covalent bond constructed hybrid dynamic HPUA networks; (H) Tensile stress-strain curve of optimized HPUA-2 under a strain rate of 100 mm min⁻¹; (I) Tensile stress-strain curves of the unnotched and notched films of HPUA. A notch of 2.5 mm in length, 1 mm in thickness, a distance of 10 mm and 5 mm in width. Deformation rate: 100 mm/min; (J) Tensile loading-unloading curves of hydrophilic HPUA at different strains of 100% to 600%; and (K) Tensile stress-strain curves of original HPUA, HPUA soaked in artificial sweat for 1-3 days at ambient condition.

FIG. 4 depicts the reactions of oxygen in UV-initiated free-radical polymerization that affect the urethane functions in HPUA through photopolymerization. During irradiation, the free radical is generated by photolysis of the initiator. The urethane segments would be subject to hydrogen abstraction at the methylene to the nitrogen atom (pathway 1). Free radical quenching by dioxygen would then convert the C—N units into products of I, with geminate heteroatoms O—C—N. In the presence of oxygen, the primary free radical is expected to be quenched and converted into a peroxyl radical and further to a more stable hydroperoxide by hydrogen abstraction (pathway 2). This would yield new CH—O bonds as in products of type II. Photolysis occurs at the urethane N—CO bond (pathway 3, decarboxylation).

FIG. 5 depicts the Fourier transform infrared spectroscopy (FTIR) characteristic peak assigned to the different OCN-PU-NCO prepolymer and the resultant HPUAs. (A) The peak intensity curves of N═C═O (the peak area around 2264 cm⁻¹) groups of HPUA at a constant temperature with different time intervals. The intensity of NCO peak at 2264 cm⁻¹ region progressively decreasing with constant temperature over time which is confirmed the reaction between —NCO group of IPDI and —OH group of HEMA. After 240 min, nearly no N═C═O prepolymer peak at 2264 cm⁻¹ was observed, indicating that the N═C═O prepolymer bond of IPDI and O—H bond of HEMA fully reacted and the reaction went to completion, with no reactants remaining; and (B) FTIR spectra of the prepolymer and HPUA with different HEMA content. The following characteristic bands in the result of HPUA were observed: 3339-3355 cm⁻¹ (amide stretching vibration of hydrogen-bonded N—H groups), 3405-3495 cm⁻¹ (amide stretching vibration of non-hydrogen bonded N—H group), 3000-2800 cm⁻¹ is due to the CH aliphatic stretching vibrations (anti-symmetric and symmetric aliphatic stretching modes of methylene group), 1728 cm⁻¹ (carbonyl stretching vibration of hydrogen-bonded C═O group), 1456 cm⁻¹ (C—H), 1537 cm⁻¹ (C—NH, bending vibrations), 1093 cm⁻¹ (O—O—C, ether oxygen of soft-segment stretching), and 1534 cm⁻¹ (C—NH, bending vibrations). The acrylate stretching vibration of the carbon-carbon double bonds (C═C) appears at 1630 cm⁻¹ and the peak at 1415 cm⁻¹ belongs to the in-plane bending vibration of C—H on C═C bonds. The peak at 990 cm⁻¹ and 948 cm⁻¹ are assigned to the out-of-plane bending vibration of C—H on C═C bonds.

FIG. 6 depicts the expansion of the FTIR absorption peak of (A) carbonyl (C═O, 1700-1450 cm⁻¹) stretching regions of HPUA films. The hydrogen-bonded carbonyl groups of the urethane (—NH—C═O—O—) are observed at 1720-1725 cm⁻¹ (stretching vibration of hydrogen-bonded C═O urethane groups), 1707 cm⁻¹ (stretching vibration of H-bonding in disordered C═O urethane regions); and (B) amide (N—H, 3600-3000 cm⁻¹) stretching regions of HPUA films. The peaks at 3339-3355 cm⁻¹ (hydrogen-bonded stretching vibration of N—H) and 3405-3495 cm⁻¹ (non-hydrogen bonded stretching vibration of N—H) are ascribed to the stretching vibration of N—H which was highly sensitive to hydrogen bond distribution.

FIG. 7 depicts the thermogravimetric analysis (TGA) characterization. Thermograms and derivative curves of HPUAs, at a heating rate of 10° C./min from room temperature to 700° C. under a nitrogen atmosphere.

FIG. 8 depicts the contact angle measurements of artificial sweat liquid on glass substrates made of the HPUA dried films. Here, ˜150 micron-thick layers of the HPUA resins were directly deposited on glass substrates and then thoroughly dried.

FIG. 9 depicts the optical properties of the HPUA. (A) Optical image of HPUA. Scale bar: 3 cm; and (B) Transmittance of HPUA film in the wide range.

FIG. 10 depicts the compilation of the major intermolecular interactions involving the urethane group and their band assignments for the N—H/C═O stretching modes. Type I: Intermolecular monofurcated interactions between urethane units lead to the formation of NH O═C hydrogen bonds; Type II: Intermolecular interactions occurring between the carbamate oxygen (O—CO) and amide hydrogen (N—H) to form an N—H···O—CO H-bond complex; Type III: Ether oxygen (—O—) of polyoxyethylene (POE) competing with the urethane carbonyl group (C═O) to form a hydrogen bond with the urethane N—H group (N—H···COC). Type IV: NH···NH hydrogen bond formed through a donor atom N and an acceptor atom N, Type IV, since the probability is too little. This suggests that Type III H-bonds (NH NH) hardly exist in the system; Type V: Ordered microdomain with hydrogen bonds in the formation of cyclic-urethane groups cis-cis; Type VI: Ordered microdomain with hydrogen bonds in the formation of cyclic-urethane groups trans-cis.

FIG. 11 depicts the mechanical properties of the HPUA. (A) Tensile stress-strain curve of HPUA elastomer films; and (B) Photographs of a HPUA-2 test specimen before and after stretching, which had a pronounced impact on the mechanical properties.

FIG. 12 depicts (A-B) stress-strain curves of the unnotched and single-edge-notched HPUA-1 and HPUA-3 with the same dimension, which were measured by the tensile tests. The HPUA film could achieve high fracture energy, considering that the polymeric network is highly crosslinked by dynamic hydrogen bonding, thus evidencing the notch insensitive stretching of the HPUA material; (C) schematic illustration of the single-edge-notched sample used for the tensile test; and (D) the photograph of tensile test of a notch insensitive and stretchable HPUA film. Scale bar: 1 cm.

FIG. 13 depicts the FTIR absorbance spectra of original HPUA-2 and HPUA-2 after being soaked in artificial sweat for 1, 2, and 3 days. No peak change for the soaked HPUA-2 film was observed after soaking in sweat for 3 days, which could be regarded as an intuitional evidence of good stability in HPUA under sweat condition.

FIG. 14 depicts (A) schematic of the enhanced conductivity from human sweat and the surface changes of the printed Ag-HPUA electrodes upon contact with sweat before and after stretching; (B) the composition and photo image of the Ag-HPUA ink. Scale bar: 2 cm; (C) and (D) the scanning electron microscope (SEM) images of Ag-HPUA electrode before and after soaking with sweat, respectively. Scale bar: 1 μm; Illustrations of the fabrication of Ag-HPUA electrodes on the textile by (E) screen-printing and (F) 3-D printing; and (G) and (H) screen-printed and 3-D printed patterns on the textile, respectively. Scale bars: 2 cm.

FIG. 15 depicts the cross-sectional SEM images of Ag-HPUA electrodes on textile (A and B) before; and (C and D) after reaction with artificial sweat. Scale bar: 100 μm in (A) and (C); and 10 μm in (B) and (D).

FIG. 16 depicts the tensile behaviors of the bare textile and printed textile. (A) Tensile stress-strain curves of the bare textile and Ag-HPUA printed textile; (B) Single cyclic stress-strain curves of the bare textile and Ag-HPUA printed textile; and (C-D) Continuous cyclic tensile loading-unloading curves of printed textile and bare textile at 50% strain without resting time between each cycle (tensile rate: 50 mm/min).

FIG. 17 depicts (A) illustration of the testing of the resistance change of textile-based Ag-HPUA electrodes after dropping the artificial sweat; (B) the scheme of the interface between the textile and the Ag-HPUA electrode, as well as the textile-enhanced contact area between active ions and Ag-HPUA electrodes; (C) artificial sweat contact angles of the Ag-HPUA and the Ag-SEBS electrode; (D) resistance changes of Ag-HPUA electrodes in contact with artificial sweats with different pH; (E) resistance changes of Ag-HPUA electrodes after soaking with NaCl/KCl/urea, NaCl/KCl/lactic acid, lactic acid, and artificial sweat solutions; (F) the SEM image of the Ag-HPUA electrode after reaction with artificial sweat. Scale bar: 30 μm; (G) and (H) high-magnification SEM images of Ag-HPUA before and after contact with artificial sweat for 30 min, respectively. Scale bar: 3 μm; (I) and (J) the conductive atomic force microscopy (C-AFM) of the Ag-HPUA electrode before and after reaction with artificial sweat, respectively; (K) the resistance of an Ag-HPUA electrode on textiles after soaking with the artificial sweat and subsequent washing by deionized (DI) water. The inset is the magnification of the marked area; and (L) the resistance changes of Ag-HPUA electrodes printed on the bare and 0.4% lactic acid-soaked textiles after contacting pH 5.5 artificial sweat.

FIG. 18 depicts the effect of Cl⁻ and lactic acid concentrations on the resistance changes of Ag-HPUA electrodes: (A) lactic acid kept at 17 mM; and (B) Cl⁻ kept at 98 mM.

FIG. 19 depicts (A) contact angle measurements of artificial sweat liquid on the Ag-HPUA printed on textile. Here, a layer of the Ag-HPUA inks were directly deposited on textile and then thoroughly dried; and (B) the comparison with the Ag-SEBS electrode.

FIG. 20 depicts the photo images of Ag flakes when soaked inside (A) urea; (B) lactic acid/urea; (C) NaCl/KCl/urea; and (D) artificial sweat solutions. Scale bar: 1 cm.

FIG. 21 depicts the SEM images of Ag flakes (A) before and (B) after reaction with lactic acid/urea; (C) NaCl/urea; and (D) artificial sweat. Scale bar: 2 μm.

FIG. 22 depicts the long-term resistance changes of Ag-HPUA electrode after dropping original artificial sweat, lactic acid/urea, and NaCl/KCl/urea.

FIG. 23 depicts the X-ray diffraction (XRD) patterns of Ag flakes before and after reaction with original artificial sweat, lactic acid/urea, and NaCl/KCl/urea.

FIG. 24 depicts the X-ray photoelectron spectroscopy (XPS) spectra of (A) survey scans; (B) Cl 2p; and (C) Ag 3 d for Ag flakes before and after reaction with original artificial sweat, and NaCl/KCl/urea.

FIG. 25 depicts the TGA characterization of Ag flakes before and after reaction with original artificial sweat, lactic acid/urea, and NaCl/KCl/urea.

FIG. 26 depicts the FTIR patterns of Ag flakes before and after reaction with original artificial sweat, lactic acid/urea, and NaCl/KCl/urea.

FIG. 27 depicts the (A) and (B) the corresponding C-AFM topography images of FIG. 17I and FIG. 17J, respectively.

FIG. 28 depicts (A) the SEM image of the artificial sweat-soaked Ag-HPUA electrode on textiles under 50% stretching. Scale bar: 300 μm; (B) the resistance vs strain plots of the Ag-HPUA textile electrode (i) without and (ii) with the presence of pH 4 artificial sweat; and (iii) original artificial sweat; (C) the low-magnification (I and II) and high-magnification (III and IV) SEM images of the stretched Ag-HPUA electrode before and after soaking with original artificial sweat. Scale bar: 20 μm in I and II, 2 μm in III and IV; (D) the resistance changes of the Ag-HPUA textile electrode under 30% cycling stretching (i) without and (ii) with the presence of pH 4 artificial sweat; and (iii) original artificial sweat; (E) the resistance change of the Ag-HPUA textile electrode during 500 cycles of 30% stretching in the presence of pH 4 artificial sweat; (F) the resistance change of one Ag-HPUA textile electrode experiencing the first 10 cycles of 30% stretching and subsequent pH 4 artificial sweat spraying. The inset is the magnification of the marked square; (G) and (H) photo images of anchoring the printed Ag-HPUA electrode on one subject's forearm for in-vivo testing. Scale bar: 3 cm; and (I) the resistance change of one Ag-HPUA electrode during the whole stationary cycling exercise of the subject.

FIG. 29 depicts the sheet resistance of the stretchable electrode.

FIG. 30 depicts the resistance change of the electrode during 100 cycles of 50% stretching.

FIG. 31 depicts the (A) single stretching; and (B) 30% cycling stretching data for original Ag-HPUA electrode and dried artificial sweat-soaked (pH=2.7) Ag-HPUA electrode.

FIG. 32 depicts the release of Ag from per area of Ag-HPUA electrodes into the artificial sweat.

FIG. 33 depicts the (A) resistance change of the printed electrode during 50 cycles of washing; and (B) resistance of electrodes after soaking, with and without strain.

FIG. 34 depicts (A) and (B) the scheme and reaction mechanism of the printed sweat-activated Zn—Ag₂O battery on the textile; (C) the photo image of four printed Zn—Ag₂O batteries connected in series. Scale bar: 2 cm; (D) polarization curve and (E) power density curve plots of the sweat-activated battery in the presence of artificial sweat with different CI-concentrations: From 0 mM to 147 mM; (F) the long-time discharge curve of the printed Zn—Ag₂O battery at the current density of 0.2 mA/cm²; (G) the discharge curve of the printed Zn—Ag₂O battery under 25% and 50% stretching; (H) the photo image of the printed batteries band on the subject's arm. Scale bar: 3 cm; (I) the real-time current density vs time plot of printed battery during the stationary cycling exercise of the subject; (J) the real-time temperature curve of the wearable temperature sensor powered by four series-connected Zn—Ag₂O sweat batteries. Inset is the photo image of the temperature anchored on the subject's hand; and (K) the voltage change of the supercapacitor charged by four Zn—Ag₂O sweat batteries during powering the wearable temperature sensor. The square is the sensor and smartphone connecting period.

FIG. 35 depicts the circuit for the 4 series-connected wearable sweat-based Zn—Ag₂O to power a wearable wireless temperature sensor.

### DESCRIPTION

It has been surprisingly found that a mild and non-harmful solution (e.g. artificial sweat, European Standard number EN1811: 2012) containing 0.5% of NaCl, 0.1% of KCl, 0.1% of lactic acid, and 0.1% of urea (weight/volume ratio) or analogues thereof) can be used to sinter and increase the conductivity of textile-based silver electrodes. This “sweat sintering” process is rapid and can take less than 5 minutes to provide a permanent change in the conductivity of textile-based silver electrodes. The stretchable electrodes contain elastomer binder and Ag-based conductive fillers. The original artificial sweat is slightly acidic with a pH of 2.7 and can be tuned with a higher pH to make it even less harmful to human skin and the textile substrate. Without wishing to be bound by theory, it is believed that in a mild acidic environment and in the presence of Cl⁻, the surfactant on the surface of the silver flakes can be partially removed and new silver nanoparticles can be formed that contact the adjacent silver, thus the initial resistance of the Ag-based electrode can be highly reduced. This results in a flexible textile-based silver electrode with enhanced properties.

Additionally, there remains a need for suitable electrodes that can be incorporated into wearable technologies in a manner that is unobtrusive and with may provide robust and secure connections even after being subjected to washing. It has been surprisingly found that such a material can be created using the method outlined above. Thus, in a first aspect of the invention there is provided a flexible textile-based silver electrode, comprising:
a flexible textile substrate having a surface; and
a polymeric silver electrode wire attached to the surface of the flexible textile substrate, the electrode wire comprising:
an elastomeric material; and
silver flakes homogeneously distributed throughout the elastomeric material,
   wherein:
the fraction of Ag⁰ in the silver flakes is from 89 to 95% relative to Ag⁺; and the hysteresis (ΔR/R₀) of the flexible textile-based silver electrode following 100 cycles of being elongated by 50% of its original dimension is from 1.1 to 2, such as from 1.3 to 1.9, such as about 1.86.

In embodiments herein, the word “comprising” may be interpreted as requiring the features mentioned, but not limiting the presence of other features. Alternatively, the word “comprising” may also relate to the situation where only the components/features listed are intended to be present (e.g. the word “comprising” may be replaced by the phrases “consists of” or “consists essentially of”). It is explicitly contemplated that both the broader and narrower interpretations can be applied to all aspects and embodiments of the present invention. In other words, the word “comprising” and synonyms thereof may be replaced by the phrase “consisting of” or the phrase “consists essentially of” or synonyms thereof and vice versa.

The phrase, “consists essentially of” and its pseudonyms may be interpreted herein to refer to a material where minor impurities may be present. For example, the material may be greater than or equal to 90% pure, such as greater than 95% pure, such as greater than 97% pure, such as greater than 99% pure, such as greater than 99.9% pure, such as greater than 99.99% pure, such as greater than 99.999% pure, such as 100% pure.

As used herein, the singular forms “a,” “an,” and “the” include plural referents unless the context clearly dictates otherwise. Thus, for example, reference to “a composition” includes mixtures of two or more such compositions, and the like.

It is believed that the physical properties of the flexible textile-based silver electrode disclosed herein are achieved due to the treatment with sweat (or a sweat-like substance). Without wishing to be bound by theory, it is believed that silver flakes on at least the surface portion of the polymeric silver electrode wire react with the sweat (or sweat-like substance) and form particles with a coarser surface and/or adjacent silver flakes merge together. These physical changes may result in the enhanced physical properties obtained by the resulting product disclosed herein.

Textiles for the purposes of the present invention include, for example, woven and knitted fabrics, bonded and unbonded nonwovens and microfibre nonwovens. These may be made from synthetic, natural fibres and/or blends thereof. The flexible textile substrate may be stretchable or non-stretchable. When used herein, “stretchable” refers to a material that can be stretched to 120% of its original size in at least one dimension upon application of a strain and recovers to its original size (or at least 90% thereof) upon removal of said strain.

It will be appreciated that any suitable elastomeric material that can be applied in a pattern on a substrate surface, and which retains this pattern after it is laid thereon may be used herein. In embodiments that may be mentioned herein, the elastomeric material may be hydrophilic. Examples of suitable elastomeric materials include, but are not limited to a silicone rubber, a styrenic elastomer, a polyurethane-based elastomer and combinations thereof (e.g. blends thereof). In particular embodiments of the invention that may be mentioned herein, the elastomeric material may be a hydrophilic polyurethane acrylate elastomer.

The elastomeric material used in the polymeric silver electrode may be provided in an uncured or a cured form. When used herein, the term “uncured” is used to indicate a material that is capable of forming crosslinks, while the term “cured” is used to refer to a material that is capable of crosslinking that has been subjected to at least partial crosslinking (e.g. from 5 to 100% of the available crosslinking sites are crosslinked). The crosslinking may occur through the backbone of the polymer and/or through pendant groups on the polymer.

In embodiments that may be mentioned herein, the uncured elastomeric material may have a formula I:

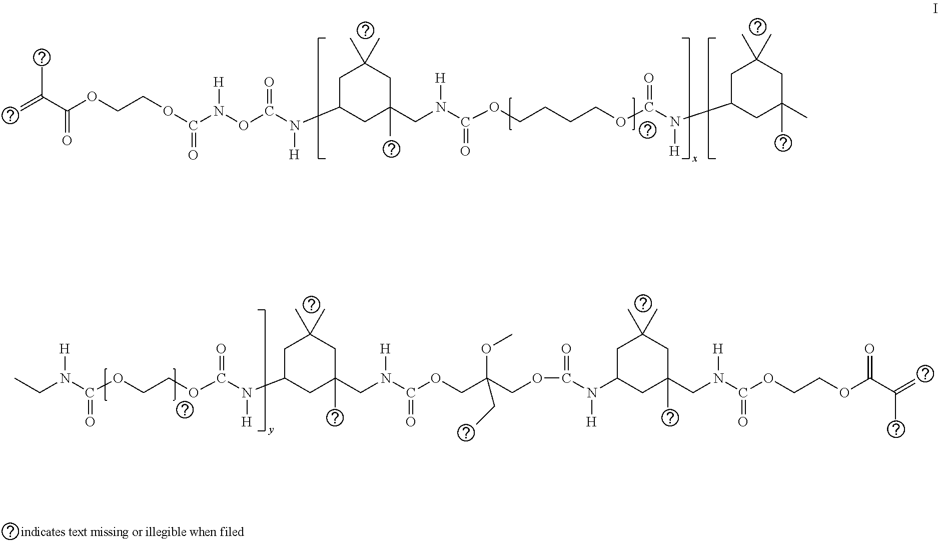

where n, x and y represent repeating units. A cured version of this uncured polymer may be the acrylate-polymerised version thereof.

Any suitable amount of silver flakes may be used in the polymeric silver electrode. For example, the weight to weight ratio of the silver flakes to elastomeric material may be from 1:0.1 to 0.1:1, such as from 1:0.5 to 0.5:1 such as about 1:0.75.

In particular embodiments of the invention, the resistance of the flexible textile-based silver electrode in a relaxed state may be from 0.1 to 1.5Ω. Additionally or alternatively, the resistance of the flexible textile-based silver electrode in certain embodiments may not exceed 7Ω when the flexible textile-based silver electrode is subjected to 500 cycles of being elongated by 30% of its original dimension in any direction. The above-mentioned parameters may apply to an electrode that has a length of 2 cm and a width of 3 cm, respectively (or vice versa).

It is noted that the flexible textile-based silver electrode disclosed herein may continue to benefit from an interaction with sweat during use. However, in order to give mechanical strength to the electrode wire it may benefit from an additional elastomeric coating layer that is applied on top of the polymeric silver electrode. That is in certain embodiments, a surface of the polymeric silver electrode wire that is not in direct contact with the textile substrate may be coated by a non-silver containing elastomeric material.

In certain embodiments, the polymeric silver electrode wire may be penetrated by parts of the textile substrate. This arrangement may be useful as it may allow the penetration of sweat into the interior portion of the polymeric silver electrode wire, thereby allowing the sintering process (described in more detail below and in the examples) to occur, which may help to provide the good properties reported herein. Thus, in certain embodiments, the flexible textile substrate may comprise a plurality of bundles of yarn on the surface of the textile substrate, where the plurality of bundles of yarn in contact with the polymeric silver electrode wire extend partly into the polymeric silver electrode wire.

The elastomeric material itself may be hydrophilic or hydrophobic in nature. However, in certain embodiments that may be mentioned herein the elastomeric material may have a water contact angle of from 10 to 25°, such as from 15 to 16°, after contact with a water droplet for 80 minutes. It is noted that the importance of contact angle depends on the application. For example, if there is a need for sweat to play a role in the use of the flexible textile-based silver electrodes, then one may prefer to use a hydrophilic material (e.g. one that has a water contact angle less than or equal to 90° after contact with a water droplet for 80 minutes (or one with the water contact angles described above). This is because it may not always be possible for the wearer to secrete a large amount of sweat during their daily activities. For applications where contact with sweat is not essential, then a hydrophobic material may be used as the elastomeric material instead (e.g. a material that has a water contact angle of greater than 90° after contact with a water droplet for 80 minutes). In such cases, if sufficient sweat or analogue solution is used for a sufficient amount of time, then the desirable properties mentioned herein may be achieved.

As will be appreciated, the flexible textile-based silver electrode may be particularly suited for use in wearable technologies. One example of a wearable technology that may be described herein is a sweat-activated battery. Thus, in a further aspect of the invention, there is provided a sweat-activated battery comprising:
a textile substrate;
a cathode comprising a cathode sweat-activated active material and a first elastomeric material on the textile substrate;
an anode comprising a sweat-activated active material and a second elastomeric material on the textile substrate; and
a current collector formed from a polymeric silver electrode wire attached to the surface of the flexible textile substrate, the electrode wire comprising:
   a third elastomeric material; and
   silver flakes homogeneously distributed throughout the third elastomeric material, wherein
a current is produced by the battery when the battery is placed into an environment including an aqueous composition comprising an inorganic chloride salt and an organic acid.

The battery may make use of any suitable sweat-activated active material for the anode and cathode.

For example, the anode sweat-activated active material may be selected from one or more of zinc powder (particles/flakes) and carbon particles (e.g. carbon black, graphite, carbon nanotube and graphene). In particular embodiments that may be mentioned herein, the anode sweat-activated active material is a combination of zinc flakes and carbon black in a weight to weight ratio of from 80:20 to 95:5, such as 90:10. In more particular embodiments of the invention, the weight to weight ratio of the anode sweat-activated active material to elastomeric material may be from 1:1 to 1:3, such as 1:2.

For example, the cathode sweat-activated active material is selected from one or more of Ag₂O powder and carbon (e.g. carbon black, graphite, carbon nanotube and graphene). In particular embodiments that may be mentioned herein, the cathode sweat-activated active material may be a combination of Ag₂O powder and carbon black in a weight to weight ratio of from 85:15 to 98:2, such as 95:5. In yet more particular embodiments of the invention that may be mentioned herein, the weight to weight ratio of the anode sweat-activated active material to elastomeric material may be from 1:1 to 1:1.5, such as 1:1.2.

As will be appreciated, the first to third elastomeric materials may be the same or different and may be selected from any suitable material. The materials and properties for the first to third elastomeric materials in the battery may be similar to the elastomeric material mentioned hereinbefore in relation to the first aspect of the invention. As such, the first to third elastomeric materials may be independently selected from one or more of a silicone rubber, a styrenic elastomer, and a polyurethane-based elastomer. In more particular embodiments, each of the first to third elastomeric materials may be a hydrophilic polyurethane acrylate elastomer.

In keeping with the first aspect of the invention, each of the first to third the elastomeric materials may cured.

In particular embodiments that may be mentioned herein, each of the first to third elastomeric materials the uncured elastomeric material may have a formula I:

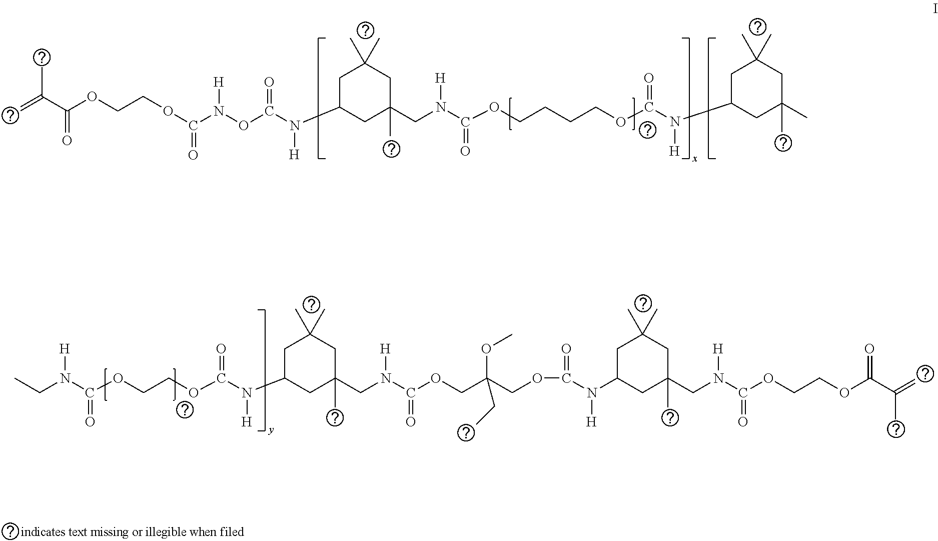

where n, x and y represent repeating units. As noted above, this material may be cured as the acrylate-polymerised version of formula I.

As will be appreciated, properties relating to the interplay if the silver flakes and the third elastomeric material may be the same as mentioned hereinbefore for the first aspect of the invention. Thus, the weight to weight ratio of the silver flakes to the third elastomeric material may be from 1:0.1 to 0.1:1, such as from 1:0.5 to 0.5:1 such as about 1:0.75. Additionally, one or more of the following may apply:
(ai) a surface of the polymeric silver electrode wire that is not in direct contact with the textile substrate is coated by a non-silver containing elastomeric material;
(aii) flexible textile substrate comprises a plurality of bundles of yarn on the surface of the textile substrate, where at the plurality of bundles of yarn in contact with the polymeric silver electrode wire extend partly into the polymeric silver electrode wire; and
(aiii) the elastomeric material has a water contact angle of from 10 to 25°, such as from 15 to 16°, after contact with a water droplet for 80 minutes.

In a third aspect of the invention there is provided a device comprising:
one or more sweat-activated batteries as described above; and
a capacitor.

As will be appreciated, additional components may be added to provide the device with any desired activity. Said device may, for example relate to a system comprising three sweat-activated batteries in series connected to a capacitor, which in turn drives a wireless temperature sensor (see the examples section below for further details).

As noted above, the production of the flexible textile-based silver electrode relies on a method of subjecting an original flexible textile-based silver electrode to a solution that is analogous to sweat. This method of production may comprise the steps of:
(a) providing a composite material comprising:
   a flexible textile substrate having a surface; and
   a polymeric silver electrode wire attached to the surface of the flexible textile substrate, the electrode wire comprising:
   an elastomeric material; and
   silver flakes homogeneously distributed throughout the elastomeric material; and
(b) bringing the composite material into contact with an aqueous solution comprising a non-toxic chloride salt and an organic acid for a period of time to form the flexible textile-based silver electrode.

It is noted that the amount of sweat produced by a subject depends on many factors, such as gender, environment, age, the amount of physical exercise undertaken, and the location on the subject's body. Without wishing to be bound by theory, it is believed that the amount of sweat needed to obtain the desired properties described herein for the flexible textile-based silver electrode disclosed herein is not always possible to obtain from a subject. This is particularly the case when a hydrophobic elastomeric material is used, which is the case for conventional materials to date, as this minimises the ability of the sweat to contact the silver wire to cause any sintering reaction to occur—much less for there to be a uniform sintering reaction across the entirety of the flexible textile-based silver electrode.

The method described above only involves the use of a mild solution (e.g. artificial sweat or an analogue there) to increase the conductivity of the electrodes in relaxed and stretched states. This method can effectively increase the conductivity of the printed electrodes in less than 5 minutes. Additionally, this method can be used with almost any textile substrate and any suitable silver-based ink, while being non-harmful to the end user. Previous methods relying on the deep permeation of ink into the textile need a high-temperature (e.g. 160° C.), which sacrifices the precision of the originally printed traces. Some reported methods use either strong acid (HCl) or high concentration NaCl solution to treat unstretchable silver-based electrodes. However, when it comes to textile-based electrodes, the strong acid and high-concentration of NaCl may degrade the property of the textile substrate, especially for some sensitive textiles, like silks and cotton. Solely weak acid and low-concentration NaCl cannot sinter the Ag-based electrodes in an effective and fast manner. Artificial sweat contains weak acid-lactic acid and a low concentration of NaCl (and other chlorides salts), both are non-harmful to textile substrates and human skin. As described herein, the synergetic effect between these two components (and their replacements mentioned herein) enables the fast and effective sintering of silver-based electrodes. Our method can also be used to fabricate wearable silver-based textile electrodes that use human sweat to increase the conductivity during exercise activities because artificial sweat has similar components to that of real human sweat. The electrode may include the hydrophilic polymer HPUA as the binder.

Any suitable pH may be used in the method disclosed above. For example, the pH may be from pH 1 to 5. However, in order to prevent damage to the skin of a wearer and/or to the textile substrate, the pH of the aqueous solution may be from 2.5 to 4.0.

Step (b) of the process above may be conducted in a washing machine. As such, the resulting product may be machine washable. For example, the product may be able to withstand up to 100 machine washes, such as up to 50 machine washes, such as up to 25 machine washes, such as from 10 to 100 machine washes without losing its functionality.

While the product may make use of an artificial sweat solution, this can be replaced by an analogous solution. For example, the aqueous solution used in the process may comprise from 0.1 to 1 wt/v %, such as from 0.4 to 0.6 wt/v %, such as about 0.5 wt/v % of an inorganic chloride salt and from 0.05 to 0.5 wt/v %, such as from 0.075 to 0.125 wt/v %, such as about 0.1 wt/v % of an organic acid. Without wishing to be bound by theory, it is believed that it is the organic acid and the inorganic chlorides in sweat that provide the desirable results and that the other components present in sweat are not required.

In particular embodiments that may be mentioned herein, the non-toxic chloride salt may be selected from one or more of the group consisting of CaCl₂), MgCl₂ and, more particularly, NaCl and KCl. In additional or alternative embodiments that may be mentioned herein, the organic acid may be selected from one or more of the group consisting of citric acid, acetic acid, tartaric acid, malic acid and, more particularly, lactic acid.

Any suitable period of time may be used for step (b) of the process above. For example, the period of time in step (b) may be at least 30 seconds to 24 hours.

In particular embodiments of the invention, it may be desired to pre-load the flexible textile substrate with an organic acid before use in the method above. This may help ensure that the desired properties are obtained consistently along the length of the polymeric silver electrode wire. As will be appreciated, the organic acids discussed above may be used in this preloading. That is, the organic acid may be selected from one or more of the group consisting of citric acid, acetic acid, tartaric acid, malic acid and, more particularly, lactic acid.

Advantages associated with the current invention include the following.
(1) For flexible and non-stretchable textile-based silver electrodes, simply soaking the printed electrodes inside the artificial sweat and then washing with water will, after drying, provide an electrode with highly increased conductivity and other properties (as mentioned hereinbefore).
(2) For stretchable textile-based silver electrodes, a strain can be imparted on textile electrodes in the presence of artificial sweat to expose the silver flakes effectively, for example by a mechanical stirrer or washing machine. Without wishing to be bound by theory, it is believed that under such washing-induced strain, more of the silver conductive filler/silver flakes will contact and react with the artificial sweat (and analogues thereof), thereby increasing the total surface area of silver in the polymeric silver wire that has been treated and hence creating more conductive networks within the polymeric silver wire. As will be appreciated, after the washing with artificial sweat, the product can be rinsed with water and dried before use or before any further manufacturing step. Washing machines are easy-to-get equipment to pre-stretch textiles and enables the sweat-sintering reaction under strain. After the washing process, the shape of textiles can be fully recovered and this is favorable for the subsequent use of the product and/or in any subsequent manufacturing steps.
(3) Artificial sweat can be reservoired in the textile substrate or a hydrogel to help sinter the silver electrodes continuously during manufacture and, possibly, during daily activities when worn on a subject. The pH of artificial sweat (or an analogue thereof) can be tuned in a human-skin friendly range, thus suitable amount of the artificial sweat can stay together with worn textile electrodes for continuous sintering without any damage to the textile substrate and human skin. Textiles substrate and hydrogel can serve as the reservoir for artificial sweat. This design is very effective to reduce elongation-induced resistance.
(4) The textile electrodes can be sintered by real human sweat when wearers are sweating. Considering the limited amount of sweat secreted by wearers, use of a hydrophilic elastomeric binder and textile substrate may be preferable to increase the absorption of sweat and hence the reaction between the electrodes and human sweat. The hydrophilic elastomeric binder is favorable for contact with human sweat and the hydrophilic textile substrate is a good reservoir for sweat once a user starts to secrete sweat. As an example of a suitable material, the highly stretchable and UV-curable hydrophilic polyurethane acrylate (HPUA) elastomer can be synthesized by the reaction of poly(tetrahydrofuran) (PTHF), polyethylene oxide (PEO), trimethylolpropane (TMP), excess isophorone diisocyanate (IPDI), and 2-hydroxyethyl methacrylate (HEMA) using dibutyltin dilaurate (DBTDL) as a catalyst.
(5) The whole electrode fabrication method in the current invention is low-cost and it involves direct printing on textiles, including screen printing and 3D printing, and then curing in ambient condition without the need for any heat or specific UV curing process or use of toxic chemicals, which is favourable for both wearable electronics and textile technologies, and is substrate-friendly and user-friendly.

### EXAMPLES

Materials

Polytetrahydrofuran glycol (PTHF, Mw=1000 g/mol, 98%) and POE (Mw=1000 g/mol, 98%) were purchased from Sigma-Aldrich and degassed at 130° C. for 3 h before use. 1,1,1-tris(hydroxymethyl)propane (TMP, Mw=134.17 g/mol, 97%), dibutyltin dilaurate (DBTDL, 95%), HEMA (Mw=130.14 g/mol, 99%), dibutyltin dilaurate (DBTDL, Mw=631.56 g/mol, 95%), acetone (anhydrous 99.5%), sodium chloride, DL-lactic acid (˜90%), potassium chloride, sodium hydroxide, 2-butanone and urea were also received from Sigma-Aldrich and used without any purification. Isophorone diisocyanate (IPDI, a mixture of isomers, 98%), carbon black and silver oxide were purchased from Alfa Aesar. Methyl ethyl ketone (MEK, 99%), 1-hydroxycyclohexyl phenyl ketone (IRGACURE® 184, Mw=204.3 g/mol, 99%), Ag flakes (10 μm), SEBS (Tuftec™ H1052) with 20/80 S/EB weight ratio, and hydrophilic textile (100% polyester knitted fabric) were obtained from Fisher Chemical, Ciba Specialty Chemicals, Puwei Applied Materials Technology, Asahi Kasei Corporation, and MHTC Technology Company, respectively. Deuterated solvents for NMR characterization were obtained from Cambridge Isotope Laboratories, Inc. DI water was used throughout the study. Zn flakes were purchased from Hunan Jinhao New Material Technology Co., Ltd.

Analytical Techniques

Nuclear Magnetic Resonance (NMR) Spectroscopy

¹H and ¹³C NMR were performed on 400 MHz Bruker DPX 400. ¹H and ¹³C NMR were carried out at ambient temperature using deuterated solvents as lock and the residual solvent or tetramethylsilane (TMS) signal as the internal standard.

Fourier Transform Infrared Spectroscopy (FTIR)

FTIR was performed on Fourier transform infrared spectroscopy-attenuated total reflectance (FTIR-ATR), Perkin Elmer, Frontier.

Thermogravimetric Analysis (TGA)

The thermal property of the hydrophilic poly(urethane-acrylate) (HPUA) film was characterized using TGA (TA Instruments Q500). 10-25 mg of HPUA samples were placed in a platinum pan and heated from room temperature (RT) to 700° C. under a nitrogen (N₂) atmosphere at a heating rate of 10° C./min.

Dynamic Mechanical Analysis (DMA)

DMA analysis was conducted on a dynamic mechanical analyzer (TA Instruments, DMA Q800) and samples were measured in a temperature range of −80 to 170° C. using a heating rate of 10° C./min in a liquid N₂ environment.

Ultraviolet-Visible (UV-Vis) Spectroscopy

UV-Vis absorption and transmission spectra were recorded with a UV-2501 PC spectrometer (Shimadzu, UV-2501 PC) in the range of 190-900 nm at ambient temperature.

Contact Angle Measurement

To measure solid-liquid contact angles between the glass and the testing artificial sweat liquids were applied on the dried HPUA films, while the contact angles were digitally measured by a contact angle meter (Data physics OCA 15 Pro).

Scanning Electron Microscopy (SEM)

SEM and high-magnification SEM characterization were performed on JEOL 7600.

Conductive Atomic Force Microscopy (C-AFM)

C-AFM was performed on Cypher S (Asylum Research). The samples were adhered on the glass substrate with a conductive wire connected to the AFM equipment.

### Example 1. Synthesis of HPUA

NCO-Functionalized Urethane Prepolymers (OCN-PTHF-NCO)

PTHF (14.50 mmol) was charged in a dried three-necked glass vessel equipped with a thermometer, a mechanical stirrer, a condenser, and an inlet of dry N₂ was degassed in a vacuum (<133 Pa) at 100° C. for 1 h to remove any moisture and then reduced to 85° C. Isophorone diisocyanate (44.95 mmol) and catalyst (DBTDL, 0.2 wt % of PTHF and IPDI, 2000 ppm) dissolved in MEK (5 mL) were added dropwise into the vessel and the resultant mixture was kept stirring at 85° C. for 6 h under an N₂ atmosphere to yield OCN-PTHF-NCO. Afterward, 20 mL of dry MEK was added to dissolve OCN-PTHF-NCO.

HPUA

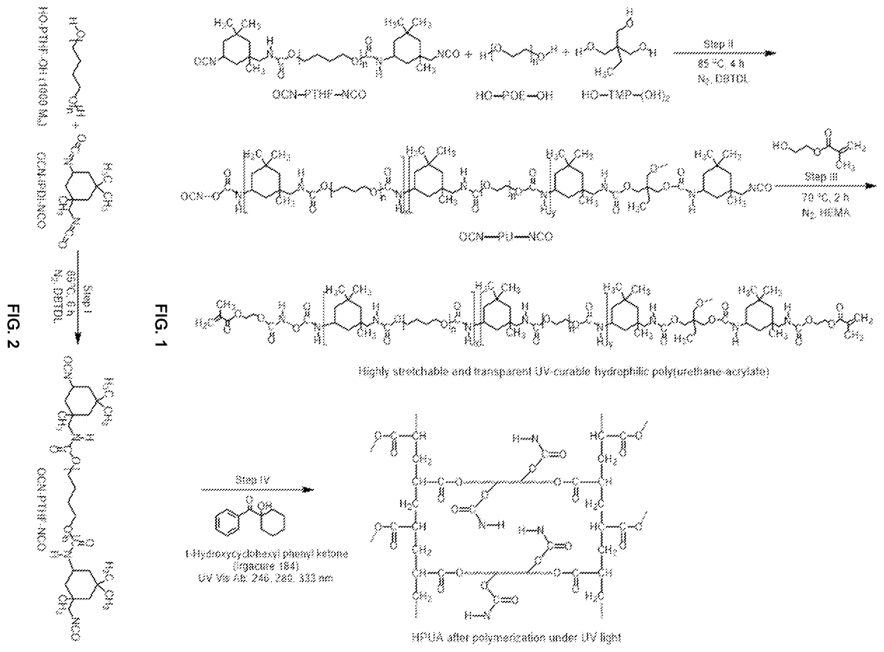

A typical procedure of the preparation of the HPUA and their chemical structures are shown in FIG. 1. The two-step synthesis routes are described briefly as follows: Firstly, POE (14.50 mmol) and TMP (7.25 mmol) were added to the OCN-PTHF-NCO prepolymer solution. The reaction was carried out at 85° C. for another 4 h with N₂ protection and then 20 mL of MEK was added to reduce the viscosity and prevent gelation. The rate of reaction has been monitored by the n-butyl amine back titration method according to ASTM D 2572-97. After the synthesis of OCN-PU-NCO, the reaction mixture was cooled down to 60° C., and OCN-PU-NCO was end-capped with 10 wt %, 20 wt % and 30 wt % HEMA to form HPUA-1, HPUA-2 and HPUA-3, respectively (FIG. 1). The resulting HPUA mixture was further stirred for 2 h at 60° C. under N₂ atmosphere to ensure all isocyanate (—NCO) groups were consumed. FTIR spectra were collected at regular time intervals, measuring the progressive decrease of the isocyanate (—NCO) region at 2270 cm⁻¹. The peak associated with the —NCO group disappeared in the final synthesized HPUA, thus signifying the formation of HPUA end-capped with acrylate double bonds.

¹H-NMR (400 MHz, CDCl₃, 25° C.) δ (ppm): 0.89 (s, 9H, —CH₃), 0.91 (s, 3H, —CH₃), 1.46 (d, 6H, —CH₂), 1.67 (q, 4H, —CH₂—), 2.86 (d, 2H, —CH₂—NH—), 3.43 (d, 2H, —CH—O—), 3.98 (s, 4H, —C—CH₂—O—), 3.39-3.42 (s, CH₂O, PTHF), 4.05-4.07 (d, OCH₂, PTHF) 5.98 (d, 2H, ═CH₂, HEMA), 5.43 (d, 2H, ═CH₂, HEMA), 7.96 (t, 1H, —NH—C═O—O—).

Results and Discussion

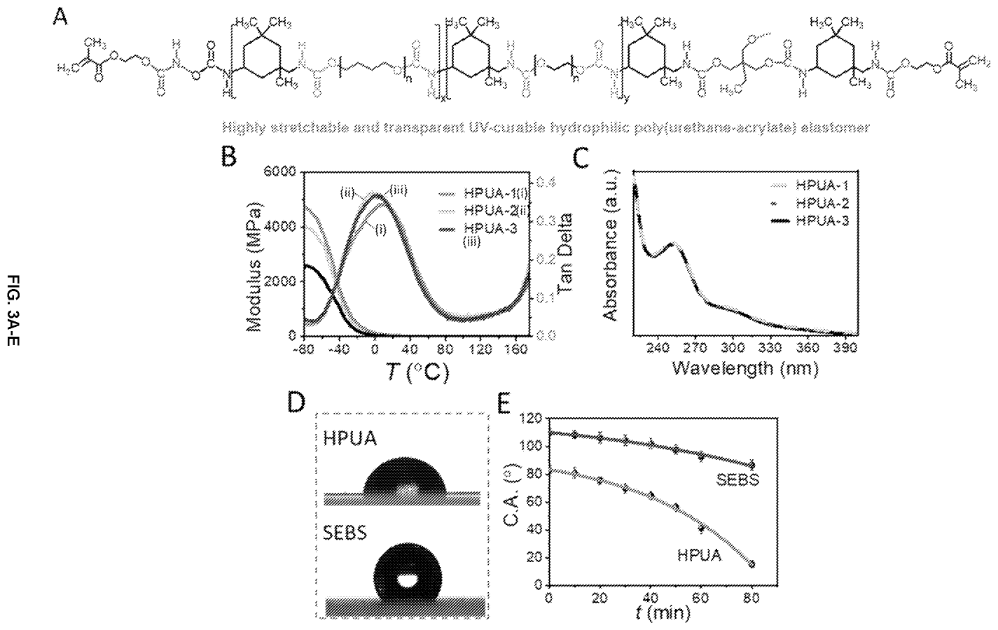

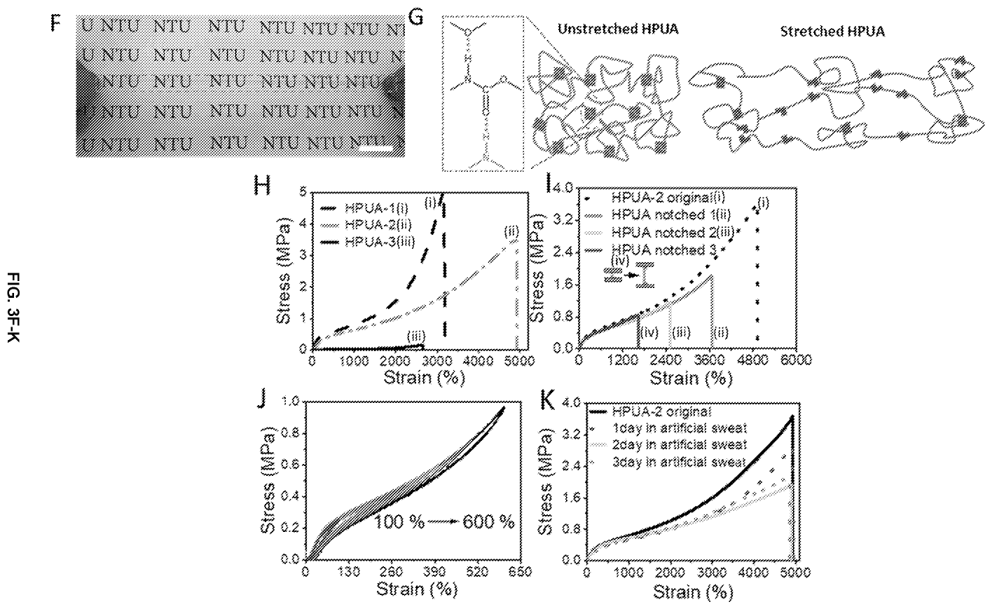

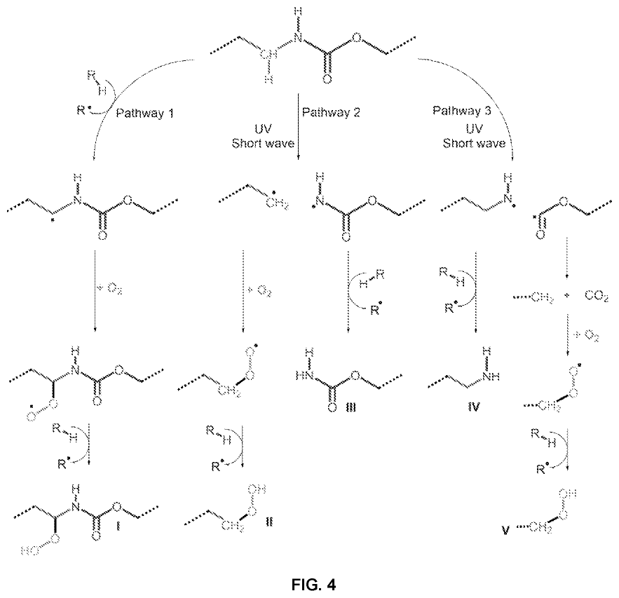

The photocurable HPUA elastomeric binder was synthesized by a one-pot step-growth polycondensation followed by radical polymerization from simply available PTHF as a diol, IPDI as a diisocyanate, hydrophilic POE as a macrodiol chain extender to yield covalently crosslinked networks, tri-functional TMP polyol as an internal crosslinker to yield covalent crosslinked PU networks, and hydrophilic HEMA as a reactive diluent, in the presence of catalyst DBTDL (FIG. 1-2). The chemical structure of the multifunctional hydrophilic HPUA elastomer is depicted in FIG. 3a. Pre-polymerized intermediates OCN-PTHF-NCO were synthesized by terminating the PTHF diol with an NCO group of IPDI, as shown in FIG. 2. Then, OCN-PTHF-NCO was subsequently reacted with hydrophilic POE and TMP to extend the polymer chains and obtain the OCN-PU-NCO prepolymer precursor (FIG. 1). The well-designed free radical acrylate (C═C) polymerization mechanism under the UV-irradiation ensures the photocurability of HPUA, as shown in FIG. 4. PTHF (—OH) was used as the soft segment (SS) due to its flexible chain that can facilitate the chain motion for better stretchability (Fu, D. et al., J. Mater. Chem. A 2018, 6, 18154-18164). Among various hard-segment (HS) candidates, IPDI (N═C═O) was selected because of its nature of two different reactivity of —NCO groups and stable mechanical performance with non-discoloring properties (Xiong, J. et al., Sci. Adv. 2020, 6, eabb4246). Furthermore, the IPDI bulky asymmetric alicyclic structure inhibits crystallization and provides sufficient chain mobility to influence UV-curability of HEMA while retaining the remarkable tensile properties (Kim, S.-M. et al., Adv. Mater. 2018, 30, 1705145). In terms of high hydrophilicity, the secondary —NCO is more active in the presence of DBTDL due to steric effect and thus, most of the —OH groups will react with the secondary —NCO, which is helpful to increase the hydrophilicity of the urethane elastomer. POE is selected as the SS because of its hydrophilic crosslinked networks (Choi, Y. S. et al., Nat. Commun. 2020, 11, 5990).

### Example 2. Characterization of UPUA

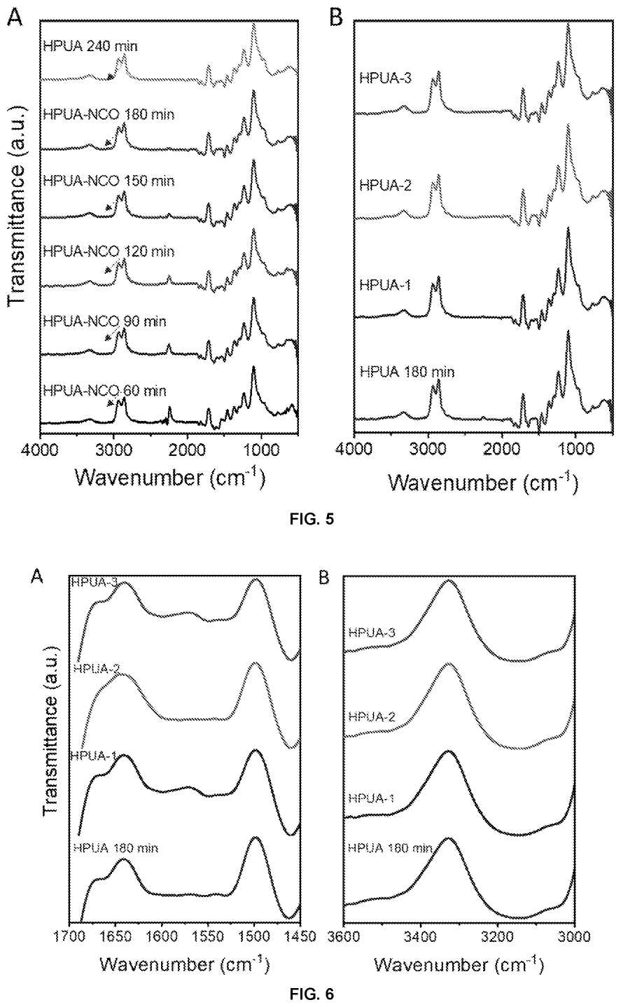

The successful synthesis of HPUA and its intermediates were verified by 1H and 130 NMR, FTIR (FIG. 5) and DMA.

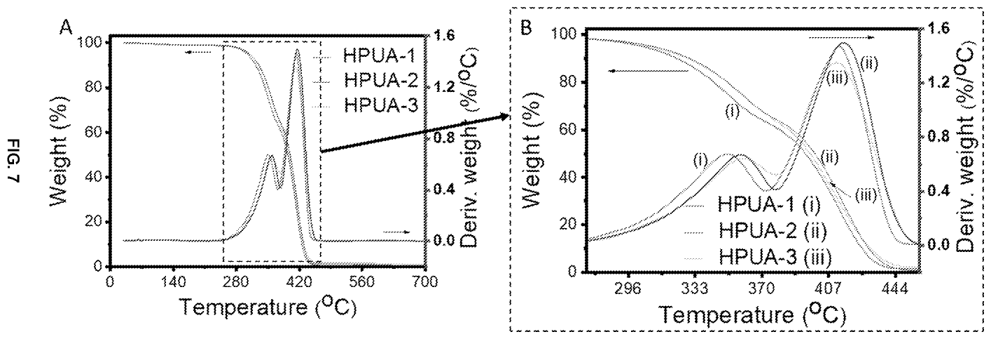

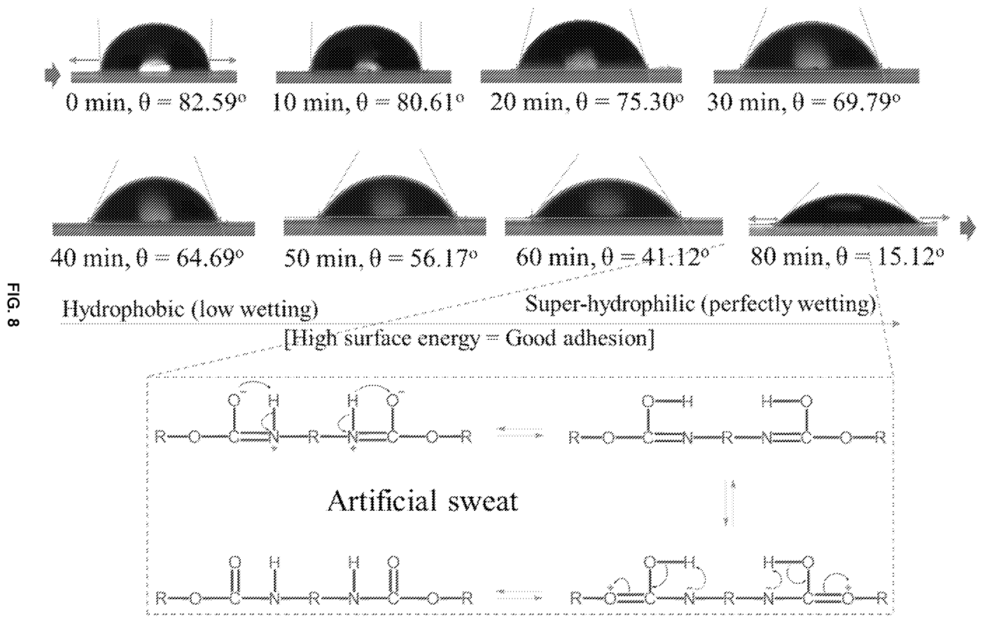

The FTIR characteristic peaks at 3318 cm⁻¹ (N—H) and 1713 cm⁻¹ (C═O) stretching vibrations indicate the formation of —NH—C═O—O groups (FIG. 6). There are negligible peaks at 1712 cm⁻¹ (C═O) and 1635 cm⁻¹ (C═C), which reveal that the monomer of IPDI has completely reacted and the reaction has fully occurred in the C═C bonds by cross-linking reaction after UV exposure, respectively (FIG. 5A). The thermal properties of HPUAs were characterized by DMA in tensile mode (FIG. 3B). The glass transition temperatures (T_{g}) observed from the loss factor (tan δ) value of HPUA-1, HPUA-2 and HPUA-3 were 8.52, -4.96, and 3.21, respectively, indicating sufficient chain mobility for the reformation of the covalent urethane bonds (NH—C═O═O—). The E′ reached a rubbery plateau after T_{g} and then continuously dropped to nearly zero at high temperature. The TGA result shows that HPUA-1, HPUA-2, and HPUA-3 exhibit relatively good thermal stability, with displayed two-step weight loss regions with peak maxima at 280° C. and 350-450° C., respectively (FIG. 7). Two-step weight loss occurred due to characteristics of the SS and hard segment (HS) of urethane processing. The initial stage of decomposition experience in the HS from diisocyanate (NCO) and the subsequent stage is due to the degradation of SS from polyol (—OH) because higher thermal energy is required for degradation of long-chain soft phase. The UV-vis absorbance spectra of HPUA-1, HPUA-2, and HPUA-3 are shown in FIG. 3C and the cutoff wavelengths of the films are in the range of 210-400 nm. The two peaks at 240-260 nm and 297-300 nm are assigned to the urethane carbonyl (C═O) and carbon-carbon double bond of the acrylate groups (C═C), indicating that the HPUA can be photopolymerized under UV illumination. They can produce π*-π* transitions of conjugate carbon-carbon double bond (C═C) and urethane carbonyl (C═O), as shown in literature (FIG. 3C, Lu, W. H. et al., Prog. Org. Coat. 2006, 56, 252-255).

### Example 3. Fabrication of HPUA Film

The freestanding film of HPUA was prepared as follows. The synthesized HPUA was diluted with anhydrous 2-butanone (85 wt %) stirred at 40° C. for 30 min. After perfect mixing, 1 wt % of 1-hydroxycyclohexyl phenyl ketone of the total weight of the HPUA resin was added. The reaction mixture was stirred for another 30 min at RT to obtain a homogeneous HPUA mixture. The resulting HPUA resin was then poured onto a glass petri dish and irradiated by a medium pressure UV lamp (365 nm) for 30 min, with a distance of 8-10 cm from the UV lamp to the focal point of the samples. The petri dish was coated with a releasing agent (WD-40 Spec Silicon Spray) to prevent adhesion of the HPUA resin to allow easy release from the petri dish. The resultant HPUA films were peeled off and placed into the desiccator at ambient condition for further analysis. The curing behavior of the HPUA film was analyzed by observing the changes in the absorption band of the acrylate group (C═C) at 1634 cm⁻¹ and 810 cm⁻¹.

### Example 4. Characterization of HPUA Film

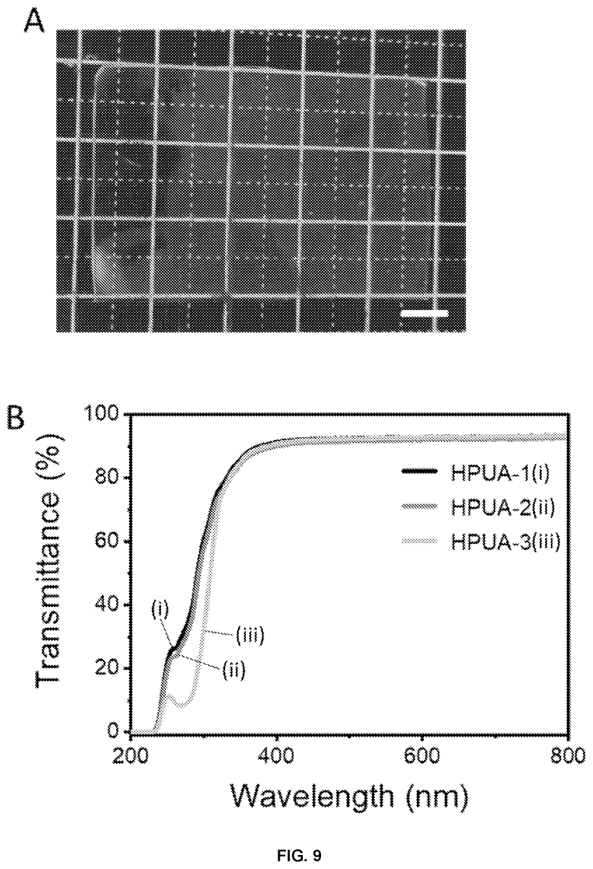

Compared with SEBS which is one of the representatives of widely-used polystyrene-based block copolymers binder in printed stretchable conductors (You, I., Kong, M. & Jeong, U., Acc. Chem. Res. 2019, 52, 63-72; and Silva, C. A. et al., Adv. Funct. Mater. 2020, 30, 2002041), the synthesized HPUA demonstrated hydrophilic property to artificial sweat. The contact angle of the HPUA binder was 82.59°, which gradually decreased to 15.12° over a period from 0 to 80 min (FIGS. 3D-E and 8). Such behaviors result in the HPUA having a higher tendency to interact with artificial sweat, owing to their hydrophilic —NH—C═O—O— functionality of the HPUAs (FIG. 8). The highly stretchable HPUA films with thickness of 0.6 mm and 0.7 mm possessed good optical properties and high optical quality, and showed high transparency with an average transmittance of ˜85% and 96%, respectively, in the visible range of 425-800 nm (FIGS. 3F and 9). Under strain, the urethane-based covalent crosslinks fix the HPUA networks. Dynamic crosslink based on urethane (—NH—C═O—O—) hydrogen bonds acts as sacrificial bonds that can rupture upon loading to dissipate energy and reform after unloading to restore the mechanical properties (schematically illustrated in FIG. 3G).

### Example 5. Tensile Tests on HPUA-1, HPUA-2, HPUA-3 and HPUA Film

Tensile Tests

All tensile test samples were prepared according to ASTM D638-10 and mechanical stress-strain was obtained with MTS criterion model 43 (MTS Systems Corporation, Eden Prairie, MN, USA) static mechanical tester with a load cell of 500 kN at a strain rate of 100 mm/min at RT. The HPUA elastomer films were prepared with different molar ratios of POE, with a sample width of 5 mm, a thickness of 0.8-0.9 mm, and a length of 10 mm. To prepare the notched sample, a notch of 2.5 mm was made in the HPUA film with 1 mm thickness, 10 mm gauge length, and 5 mm width.

Results and Discussion

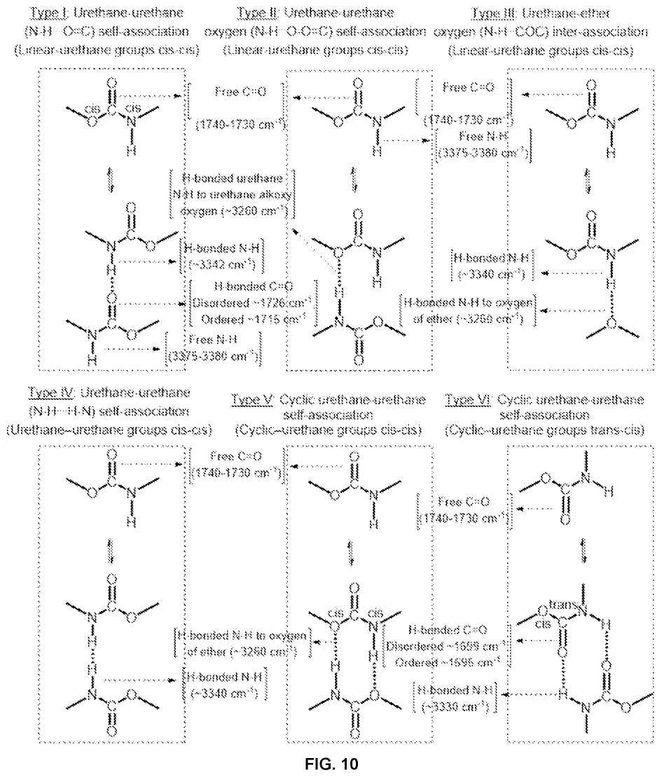

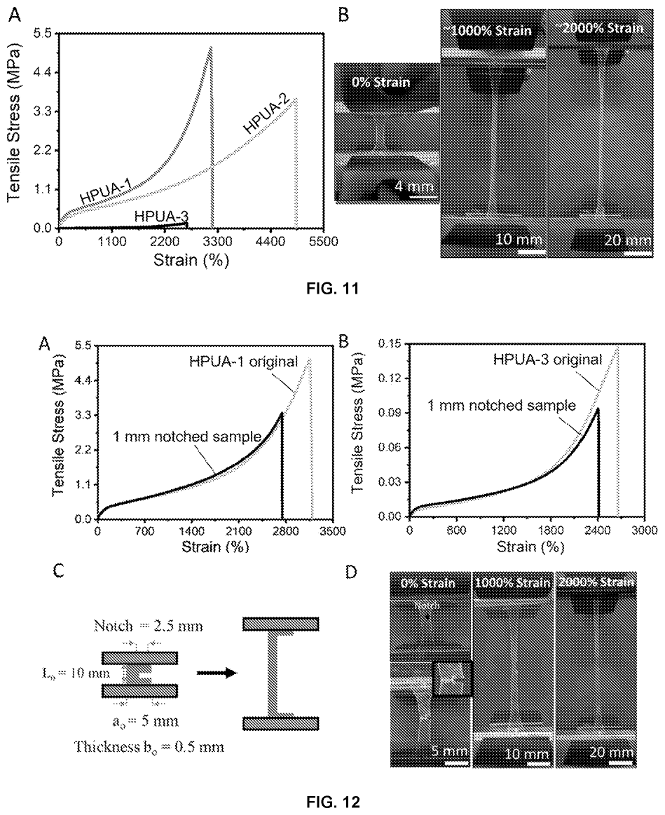

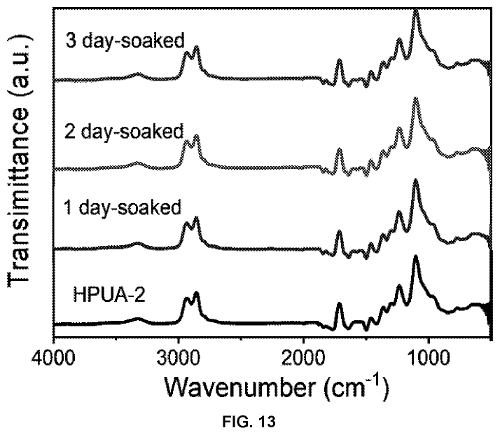

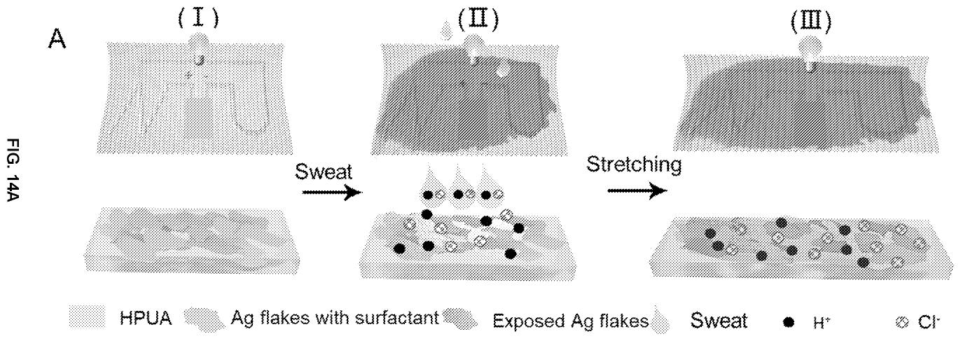

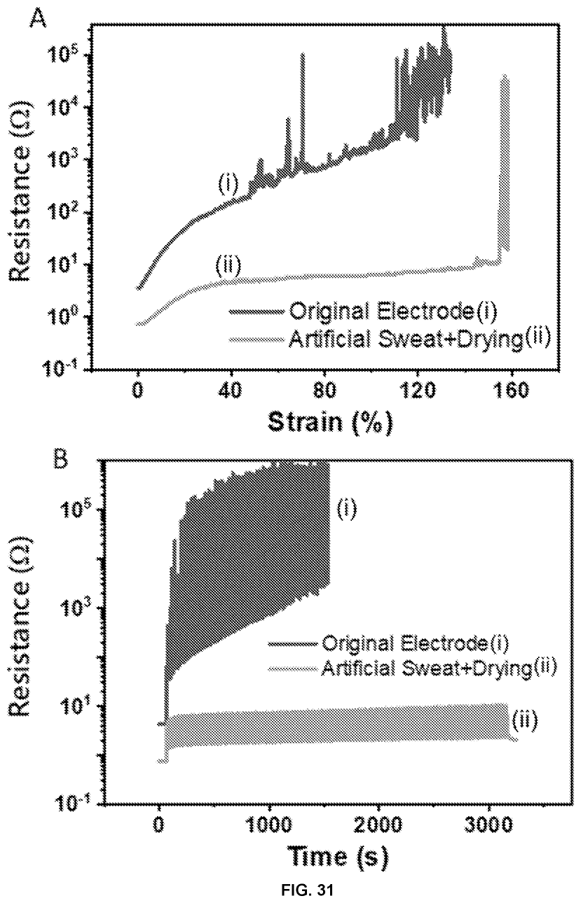

The tensile-test results show that HPUA-2 exhibited superior mechanical properties (FIG. 3H). The high stretchability can be attributed to the presence of a large number of hydrogen bonding in the N—H and C═O urethane regions as shown in FIG. 10. The tensile strength and elongation at the break of HPUA-2 were 3.69 MPa and 4954.83%, respectively. The incorporation of HEMA dramatically changes the mechanical properties with improved tensile strength and stretchability (FIG. 11). However, the increase of the HEMA content to 30 wt % dramatically reduces the stretchability and tensile strength of HPUA-3, owing to the distribution of the HSs in the carbamate linkage and reduction in the crosslinking density. The notched HPUA specimen (ASTM D412) exhibited good tear resistance behavior (FIGS. 31 and 12), of which HPUA-2 was the best one. Even with a 2.5 mm notch of the total width (5 mm), it could still bear the strain at break up to 1569.20% because of its fixing capability on the dynamic crosslinks based on hydrogen bonds in the —NH—C═O—O— network structure. Repeated cyclic tensile test and qualitative loading-unloading test were performed and it showed minimal hysteresis with optimal elastic properties of the HPUA binders due to the strong reformation capability of hydrogen bonds on the N—H group (FIG. 3J). As the electrode needs to be in contact with human sweat, the stability of the HPUA binder in sweat was evaluated by tensile-strain test and FTIR. After soaking in artificial sweat, no change in color could be identified and the tensile strains of the soaked HPUA-2 film remain the same as the original unsoaked one, confirming its excellent stability in artificial sweat (FIG. 3K). FTIR spectra of original HPUA-2, and HPUA-2 after 1 to 3 days of soaking show no changes in the molecular structure after long-time artificial sweat absorption (FIG. 13).

### Example 6. Formulation of Ink and Electrode Printing

Formulation of Ag-HPUA Ink and Ag-HPUA Electrode Printing

Amber glass vials were used as containers to avoid the photo-curing of the ink before printing. 0.75 g HPUA was mixed with 1 g Ag flakes by shaking on a vortex mixer for 10 min. A stainless steel stencil (Micro Tech Technology, Shenzhen, China) fabricated by laser cutting with a thickness of 200 μm was applied to perform the screen printing. Electrode patterns were designed on Auto CAD software. The electrodes were directly printed on top of the hydrophilic textile in a lab-made black box and then cured in the ambient lab environment for 30 min. A 3D printer called System 30 M manufactured by Hyrel 3D (USA) with a 0.36 mm nozzle was used to perform the 3D printing on textile. The printing speed was 10 mm/s and the curing process was finished in a room environment without heating and UV lighting. The size of textiles was 20 mm*30 mm and Ag-HPUA electrodes with a size of 3 mm*30 mm were printed in the center of textiles.

Formulation of Ag-SEBS Ink and Ag-SEBS Electrode Printing

The Ag-SEBS ink was formulated by mixing Ag flakes with SEBS resin (3 g of SEBS/10 ml of toluene) at a weight ratio of 1:0.75 under shaking by a vortex mixer for 1 h (MX-S, DLAB Scientific Inc). The printing of Ag-SEBS electrode was performed by following the protocol above except Ag-SEBS ink was used instead of Ag-HPUA ink.

Results and Discussion

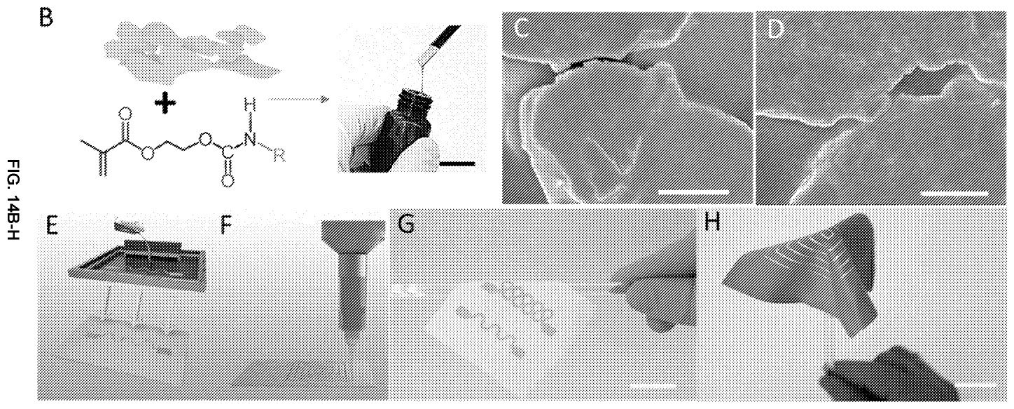

FIG. 14B shows the formulation of the ink for Ag-HPUA, in which the Ag flakes and HPUA serve as the conductive fillers and elastic binder, respectively. Ag flakes have been widely used as conductive fillers for printed stretchable conductors considering their high conductivity, ease of forming conductive percolation, and scalable manufacturing process (Matsuhisa, N. et al., Nat. Mater. 2017, 16, 834-840). The massive production of Ag flakes involves the syntheses of Ag nano/microparticles and subsequent ball milling. To avoid the cold welding and severe oxidation of Ag particles, fatty acid surfactants were added to form a layer of lubricant. The lubricant layer increases the dispersion of Ag flakes in ink formulation but decreases the conductivity of Ag flakes-based electrodes for its electrical insulating nature (Lu, D. & Wong, C. P., J. Therm. Anal. calorim. 2000, 59, 729-740). Human sweat is relatively acidic (pH=4˜6.8, Mena-Bravo, A. & Luque de Castro, M. D., J. Pharm. Biomed. Anal. 2014, 90, 139-147) and rich in Cl⁻ ions and both factors are favorable for the chemical sintering of Ag flakes (Sun, S. et al., J. Mater. Sci. Mater. Electron. 2016, 27, 4363-4371; and Grouchko, M. et al., ACS Nano 2011, 5, 3354-3359).

### Example 7. Characterization of Ag-HPUA Printed Textile Sweat-Enhanced Conductivity

The sweat-enhanced conductivity was performed by using a multimeter (DAQ6510, Keithley) to test the resistance change of electrodes with one pass printing (length: 2 cm, width: 0.3 cm) after adding the artificial sweat. The artificial sweat was prepared based on the European standard. The composition of the original artificial sweat contained 87 mM NaCl, 13 mM KCl, 17 mM of lactic acid, and 16 mM of urea, and the original pH was 2.7 (Liu, G. et al., Sens. Actuators B Chem. 2016, 227, 35-42). pH was measured using a pH meter (HI 2020F edge, HANNA Instruments) and tuned by adding 0.1 M NaOH. The stretching test was performed on electrodes with 3 passes of printing using a motorized force test stand (ESM303, Mark-10) with a speed of 10 mm/min. The speed of cyclic stretching was 20 mm/min. The surface conductivity of the electrode was tested by conductive-atom force microscopy (Asylum Research Cypher S). XRD and XPS were characterized by a Shimadzu powder diffractometer (Cu Kα, λ=1.5406 Å) and a PHI Quantara II, respectively. FTIR and TGA were used to characterize the functional groups and weight percentage of surfactant on Ag flakes, respectively. The electrical hysteresis is defined as the resistance increase after the cycling stretching.

Results and Discussion

When the printed electrodes encounter human sweat, the acidic environment, and Cl⁻ work together to partially remove the insulating lubricant layer and increase the contact among adjacent Ag flakes by redepositing Ag from dissolved Ag⁺, making the surface of Ag-HPUA electrodes rougher, as shown in FIG. 14C-D. This effect gives the printed Ag-HPUA electrode enhanced conductivity in both original and stretched states compared with dry electrodes without sweat (FIG. 14A).

HPUA with ambient photo-curable property, hydrophilic nature, and high stretchability was synthesized to serve as the binder to increase the favorability of printing, accessibility of sweat, and endurability to mechanical deformation, respectively. The photoinduced HPUA elastic binder composed of hard-segments made up of carbamate groups (—NH—C═O—O—) and SS made up of aliphatic polyether (—O—) or polyester (—CO—O—) backbone is capped with acrylate (C═C) functionality at each end. Hydrogen bonds mainly form between N—H groups and C═O groups on the hard domains. In the HPUA synthesis, HEMA and POE are the key components in the design of photo-curable HPUA. Beyond acting as the reactive diluent to tune the viscosity of the prepolymer for the ease of printing, HEMA is crucial for the double bond of the acrylate (C═C) group on the covalent networks (Parida, K. et al., Nat. Commun. 2019, 10, 2158). The POE can enhance the hydrophilicity due to their ether oxygen bonds on SS (Kokkinis, D., Schaffner, M. & Studart, A. R., Nat. Commun. 2015, 6, 8643). The HPUA elastomer includes a —HN—(C═O)—NH-containing first structural unit capable of forming a strong hydrogen bond and a —HN—(C═O)—NH-tipped with acrylic units capable of forming radical polymerization with the carbon-carbon double bonds at the end of the chains which are bound to the polymer main chain. The strong hydrogen bond imparts flexibility and mechanical strength, while the hydrogen bond with the acrylic unit imparts UV-curability and hydrophilicity. The fast ambient photo-curable nature of HPUA polymer enables green printing without the massive use of organic solvents, and the potential for complex and high-precision structures design in 3D printing (Patel, D. K. et al., Adv. Mater. 2017, 29, 1606000). Considering the low sweat generation on some occasions, the hydrophilic HPUA binder favors the contact between human sweat and Ag-HPUA electrodes.

Comparing with commonly used thin polymer film substrates, the hydrophilic textile substrate used here facilitates in-situ sweat sampling, and acts as a reservoir. Sweat reservoiring capability and porous structure of textiles give prolonged reaction time and enhanced surface area for printed electrodes to contact with sweat. Besides, the component of human sweat varies with gender, secretion area, surrounding, time of day, age, and sweating rate, which will impede the completeness of sintering effects. The textile substrate can be used to pre-store active substances, such as lactic acid and Cl⁻ salt, to weaken the effects of irregular sweating behavior of wearers. In our design, the whole electrode fabrication involves the direct printing on textiles, including screen printing and 3D printing (FIG. 14E-H), and then curing in ambient condition without any heat or specific UV curing post possess, which is favorable for both wearable electronics and textile technologies. The elaborate conductive filler selection, well-designed HPUA binder structure, and sweat soaking friendly textile substrate endowed our printed electrode to be in good contact and reaction with sweat to enhance the conductivity in both relaxed and stretched states.

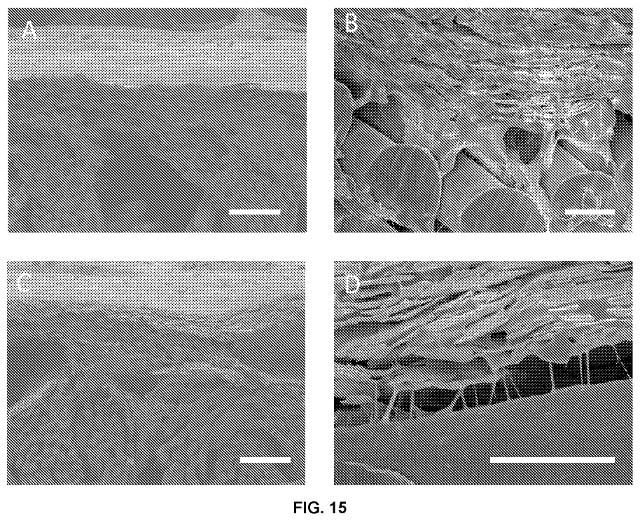

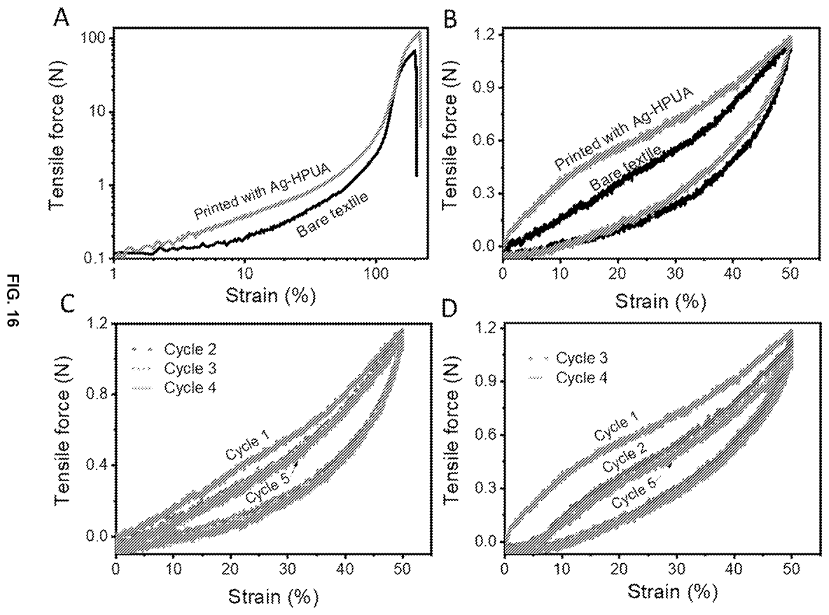

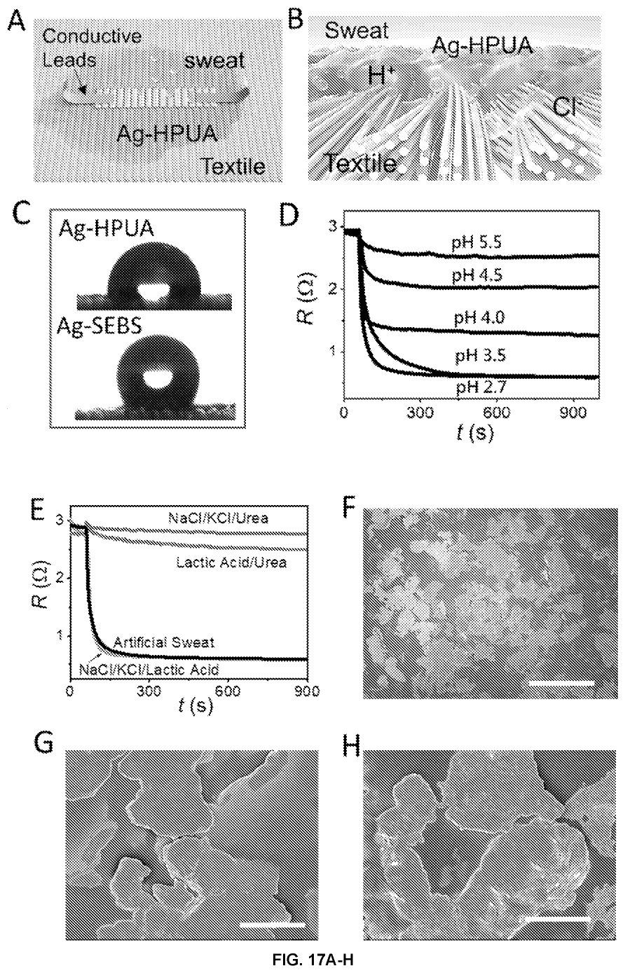

The printed electrodes attached well on the top of the textile substrate after printing, as shown in the cross-sectional SEM images of the printed Ag-HPUA electrodes before and after soaking with sweat in FIG. 15. Uniaxial single and 50% cycling stress-strain curves of the bare and the printed textiles were measured (FIG. 16), indicating that the printing of a layer of Ag-HPUA electrode has a minor effect on the mechanical properties of the textile. Compared with using thin polymer film as the substrate, direct printing of ink on the porous textile makes the bottom part of the electrode fill with fiber bundles and with a higher surface area. This design is favorable for the reaction between the printed electrode and sweat. The hydrophilic fiber bundles introduce the sweat solution to the neighboring area of electrodes and thus, more reactions among the ions in sweat and electrodes were initiated, as shown in FIG. 17A-B. Meanwhile, the well-designed hydrophilic HPUA binder can enhance the affinity between sweat and electrode, which is valuable when insufficient sweat is secreted by wearers, especially considering the pH of sweat generated in the initial sweating period with a limited amount is relatively lower than that of subsequent sweat and lower pH is more preferable for the sintering reaction (Emrich, H. M. et al., Pediatr. Res. 1968, 2, 464-478). The contact angle between the Ag-HPUA electrode and sweat was smaller at around 98.9°, whereas the contact angle between Ag-SEBS electrodes and sweat solution was 128.2°, as shown in FIG. 17C. Both contact angles are higher than respective bare polymer films, resulting from the addition of hydrophobic Ag flakes.

The sweat can instantly decrease the resistance of Ag-HPUA electrodes and the resistance loss induced by sweats with different pH is shown in FIG. 17D. The capability of sweat to reduce the resistance of printed Ag-HPUA electrodes increased with decreasing pH. When the original artificial sweat without pH tuning was added to Ag-HPUA textile electrodes, the resistance decreased from 3Ω to 0.6Ω in 14 min. The 50% and 90% resistance reduction were reached after 8.5 s and 66 s respectively, showing the fast reaction between original artificial sweat and printed Ag electrodes. As the pH increased from 3.5 to 5.5, the intensity of the resistance reduction gradually decreased but was still obvious within 2 min, suggesting that this increase in conductivity is highly related to the pH of artificial sweat. This pH range covers the pH of most people when no sweat stimulation drugs are used to secrete perspiration, for example, the pilocarpine (Herrmann, F. & Mandol, L., J. Invest. Dermatol. 1955, 24, 225-246).

Therefore, the UV-curable inks that contain UV-curable hydrophilic binder and Ag flakes (FIG. 14B) can be printed on textiles by screen printing and 3D printing, as shown in FIG. 14E-H.

### Example 8. Key Components Inside Sweat that Enhance Conductivity of Ag-HPUA Electrodes

To understand the key components inside sweat that enhance the conductivity of Ag-HPUA electrodes, resistance change of the Ag-HPUA electrodes after soaking with 4 solutions including lactic acid/urea, NaCl/KCl/urea, lactic acid/NaCl/KCl, and original artificial sweat was studied by following the sweat-enhanced conductivity protocol in Example 7.

Soaking of Ag-HPUA Electrodes

After the curing of Ag-HPUA electrodes, they were soaked in 2 ml of one of lactic acid/urea, NaCl/KCl/urea, lactic acid/NaCl/KCl, and original artificial sweat solutions for 15 h. The resistance of the four electrodes was measured by a multimeter (Keithley DAQ6510).

Immersion of Ag Flake Powders

The immersing of Ag flake powders inside four solutions was performed by dropping Ag flakes (0.3 g) into glass vials with 2 ml of one of urea, lactic acid/urea, NaCl/KCl/urea, and artificial sweat solutions, followed by shaking on a vortex mixer (MX-S, DLAB Scientific Inc).

Results and Discussion

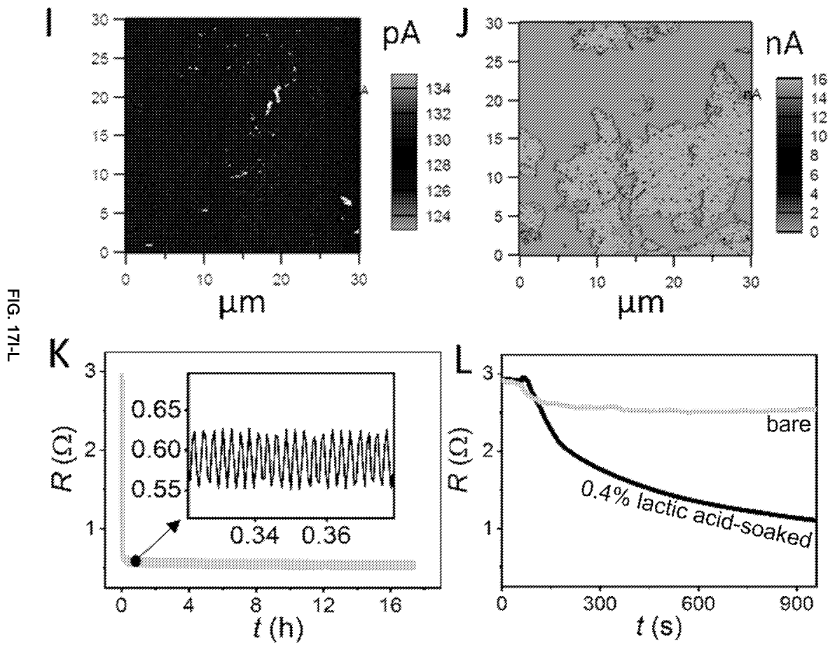

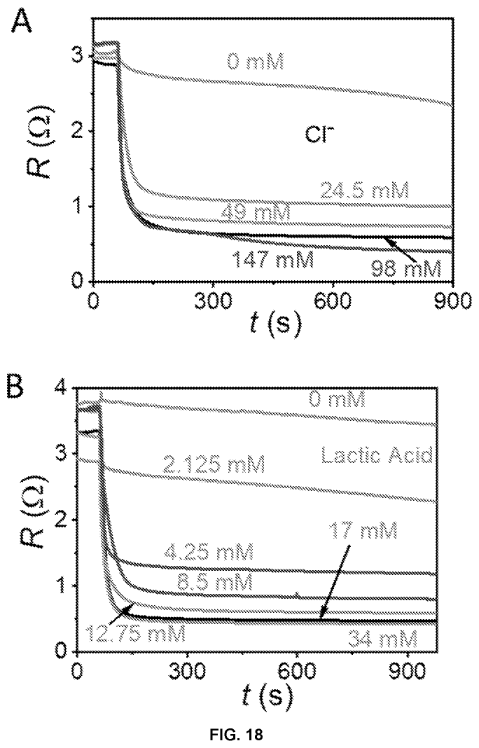

All the artificial sweats with different pH showed the capability to quickly reduce the resistance of Ag-HPUA electrodes. Different artificial sweats can be chosen based on the textile substrate's resistance to pH. 5 solutions containing urea, lactic acid, Cl⁻, lactic acid, and Cl⁻, and artificial sweat were explored, as shown in FIG. 17E. The lactic acid/NaCl/KCl solution had a similar capability to that of artificial sweat to reduce the resistance of electrodes, whereas lactic acid/urea and NaCl/KCl/urea had minor effects within 14 min, suggesting that the enhanced conductivity comes from the synergistic function from lactic acid and NaCl/KCl. The effect of lactic acid and NaCl/KCl is illustrated in FIG. 18. It is clear that even adding a little amount of NaCl/KCl (24.5 mM) and lactic acid (2.125 mM) in lactic acid/urea and NaCl/KCl/urea solution, respectively, gave much more prominent resistance reductions, further confirming that the lactic acid and NaCl/KCl work together to enhance the conductivity of printed electrodes.

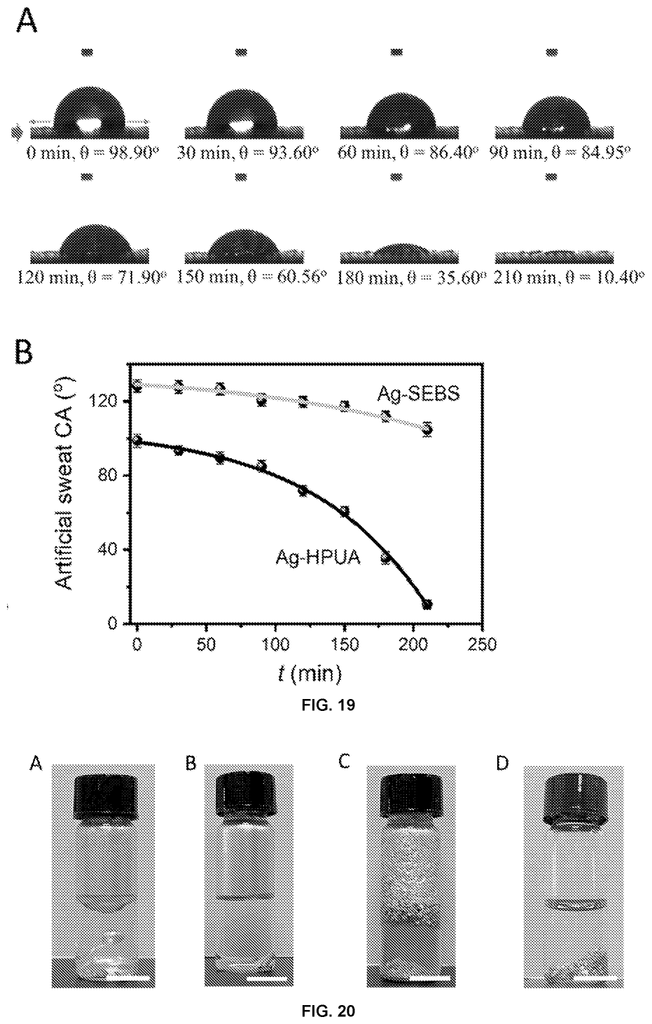

The fast resistance drop likely comes from the reaction between the exposed Ag flakes of the Ag-HPUA electrode and sweat instead of the interaction/reaction between the inner Ag flakes. The change in resistance was faster than the drop in contact angle as a function of time (FIG. 19), indicating that the surface Ag flakes reacting with sweat play a dominant role in the resistance reduction. The SEM images of electrodes after the reaction with artificial sweat are shown in FIG. 17F. Original artificial sweat with pH 2.7 was chosen to clearly show the reaction between artificial sweat and printed electrodes. The Ag-HPUA matrix remained intact after reacting with artificial sweat. However, the surface of exposed Ag flakes became coarser and some adjacent flakes merged, as shown in high-magnification SEM images (FIG. 17G-H).

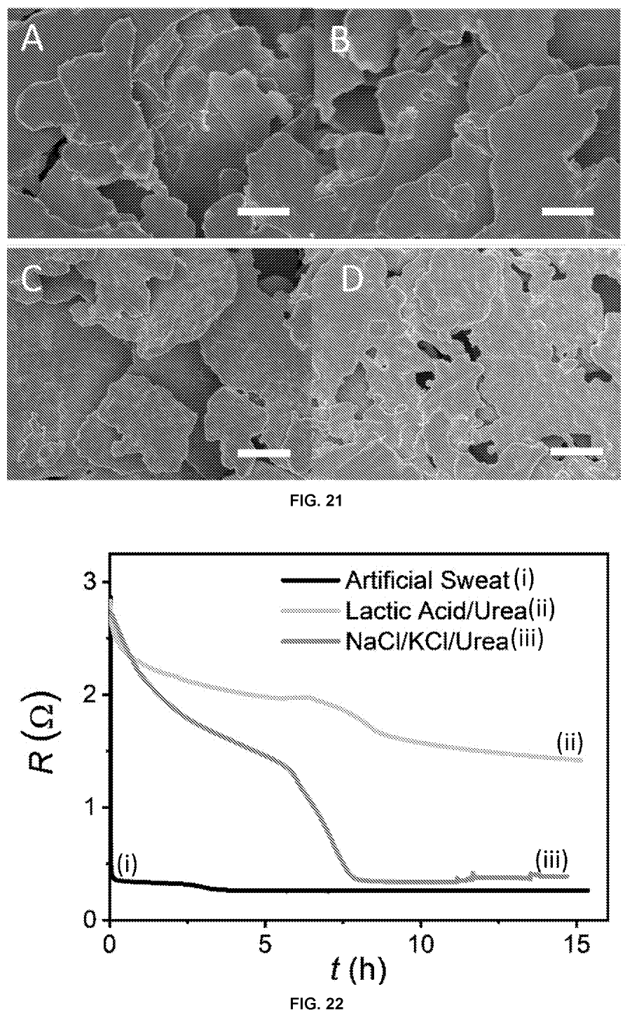

To further unveil the reaction between Ag-HPUA and artificial sweat, Ag flake powders were immersed inside the urea, lactic acid/urea, and NaCl/KCl/urea solutions, and artificial sweat. The lubricant layer on the surface of Ag flakes is made from hydrophobic fatty acid. This is the reason why most Ag flakes in urea solution, lactic acid/urea, NaCl/KCl/urea solution stay on the top of the solutions, as shown in FIG. 20. However, all Ag flakes aggregated together and dropped to the bottom of the glass vials in the artificial sweat solution, suggesting that artificial sweat containing both lactic acid and Cl⁻ ions cause the most intensive reaction with Ag flakes. The SEM images of Ag flakes after mixing with different solutions are shown in FIG. 21. Similar to the exposed Ag flakes in Ag-HPUA electrodes, the surface of artificial sweat-treated and NaCl/KCl/urea-treated silver flakes became coarser, whereas lactic acid/urea-treated Ag flakes had a smooth surface like pristine Ag flakes, showing that Cl⁻ is the key factor to induce the change in surface roughness. Even though a slight aggregation occurred in the NaCl/KCl/urea solution and a coarser surface on Ag flakes was resulted, solely having Cl⁻ ions cannot fully remove the surfactants on the flakes (as evident from the partial settling of Ag flakes at the bottom of the glass vial). The coexistence of the lactic acid and NaCl/KCl would be essential for sweat sintering of Ag flakes.

It has been reported that both H⁺ and Cl⁻ can remove the lubricant and increase the conductivity of the Ag-based electrodes (Sun, S. et al., J. Mater. Sci. Mater. Electron. 2016, 27, 4363-4371; Grouchko, M. et al., ACS Nano 2011, 5, 3354-3359; and Lee, S. J. et al., Nanoscale 2014, 6, 11828-11834). The long-term resistance change of Ag-HPUA electrodes after soaking in lactic acid/urea and NaCl/KCl/urea is shown in FIG. 22. In the presence of lactic/acid/urea and NaCl/KCl/urea solutions, the resistances of the Ag-HPUA electrodes experienced a continuous reduction in 15 h, coming from the effects of H⁺ and Cl⁻, respectively, though the resistances of both Ag-HPUA electrodes had minor declination within 14 min. In particular, after 6 h, the Ag-HPUA electrodes with NaCl/KCl/urea and lactic acid/urea solutions began to go through faster resistance reduction, which may result from the evaporation-induced high concentration of Cl⁻ ions and lactic acid.

Lactic acid plays a similar role as short-chain acids, such as malonic acid, adipic acid (Li, Y. et al., 9th International Symposium on Advanced Packaging Materials: Processes, Properties and Interfaces (IEEE Cat. No. 04TH8742). 2004 Proceedings., 2004, 1-6), acetic acid (Lu, D., Tong, Q. K. & Wong, C. P., IEEE Trans. Compon. Packag. Technol. 1999, 22, 365-371), and sulfuric acid (Tan, F., Qiao, X. & Chen, J., Appl. Surf. Sci. 2006, 253, 703-707), which could partially or fully remove or reduce the fatty acid-based lubricants. Besides, H⁺ is helpful in the dissolution of Ag through the following reaction (Li, X., Lenhart, J. J. & Walker, H. W., Langmuir 2010, 26, 16690-16698; and Peretyazhko, T. S., Zhang, Q. & Colvin, V. L., Environ. Sci. Technol. 2014, 48, 11954-11961):

4Ag+O₂→2Ag₂O (1)

Ag₂O+2H⁺→2Ag⁺+H₂O (2)

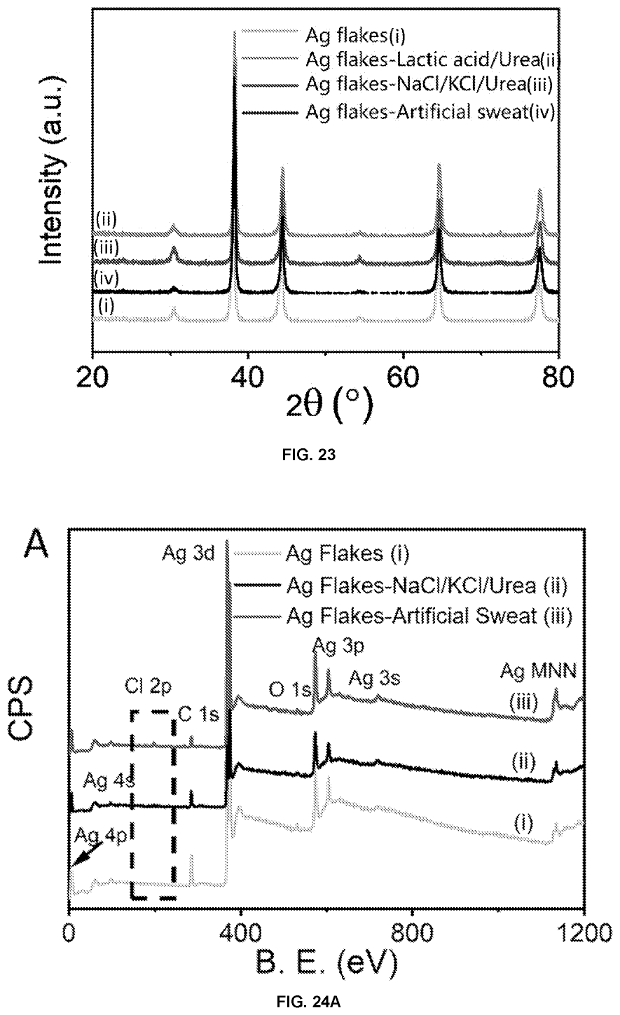

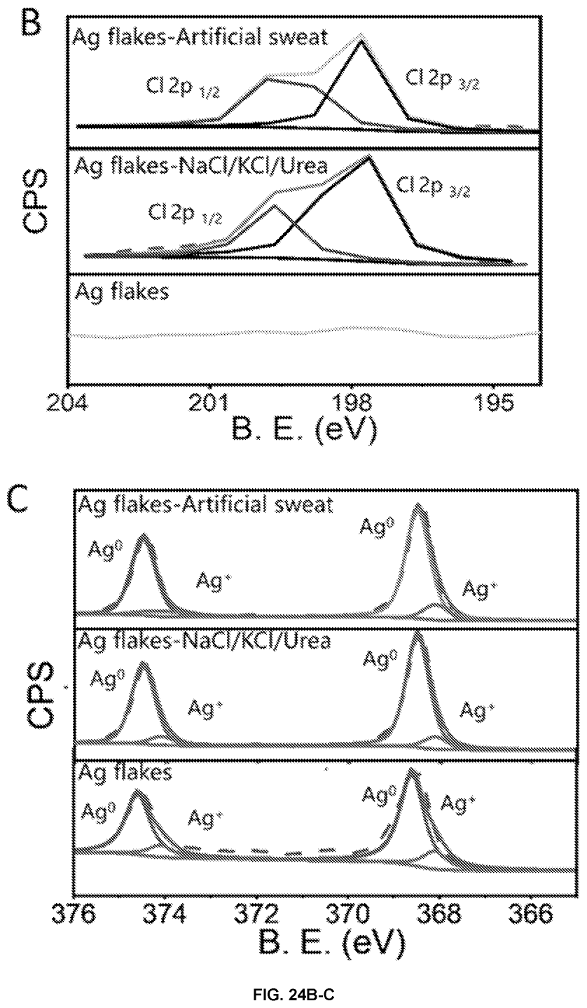

However, the reaction between Ag-HPUA and urea/lactic acid solution is not obvious because the concentration of lactic acid is low at 0.1%, and lactic acid is a weak acid that is hard to dissociate completely to release H⁺ for lubricant removal and the release of Ag⁺. Beyond removing the lubricant, the Cl⁻ ions have adverse effects on the dissolution and agglomeration of Ag flakes. On one hand, the Cl⁻ ions have a high affinity with Ag⁺, which will accelerate the dissolution of Ag⁰ to Ag⁺. The Cl/Ag ratio decides the interaction between Ag and Cl⁻ to form insoluble AgCl or soluble AgClₓ^{1-x} species (Levard, C. et al., Environ. Sci. Technol. 2013, 47, 5738-5745). Low Cl/Ag ratio forms AgCl which impedes the further dissolution of Ag⁰, whereas high ratio induces the formation of soluble Ag—Cl species which increases the dissolution rate (Li, Y. et al., Environ. Sci. Technol. 2018, 52, 4842-4849). In our case, the ratio of Cl/Ag is relatively high and a negligible amount of insoluble AgCl was formed due to the lubricant layer which limited the exposed surface area of Ag flakes. The XRD in FIG. 23 shows that all the diffraction peaks of NaCl/KCl/urea and artificial sweat-treated Ag flakes belong to Ag and no AgCl and other impurities are detected. The XPS survey scans in FIG. 24A show that weak Cl 2p peaks can be detected in NaCl/KCl/urea and artificial sweat-treated Ag flakes. The peaks at 199.6 eV and 198 eV can be assigned to Cl 2p1/2 and Cl 2p3/2 of AgCl, respectively, as shown in FIG. 24B (Nehal, M. E. F. et al., Optik 2020, 224, 165568). Both Ag⁰ and Ag⁺ with the spin-orbit doublets (the separation was 6 eV) can be found in the Ag 3 d spectra (FIG. 24C). The atomic percentage of Ag⁰ in Ag flakes was 83%. After treatment with NaCl/KCl/urea and artificial sweat, the fraction of Ag⁰ increased to 90% and 94%, respectively, suggesting that most of the new formed nanoparticles are Ag.

In the dynamic equilibration of Ag⁰-Ag⁺ system, some Ag⁺ can redeposit to Ag₀. The Cl⁻ ions induce the aggregation of Ag⁰ by decreasing the surface double electrical layer of the Ag particles via elongated ionic length and partially destroying the absorbed lubricant surfactant at high concentration (Grouchko, M. et al., ACS Nano 2011, 5, 3354-3359; and Nehal, M. E. F. et al., Optik 2020, 224, 165568). As a result, the redeposited Ag (mostly) and precipitated AgCl make the Cl⁻ treated Ag flakes coarser and more liable to aggregation compared with lactic acid/urea-treated Ag flakes. However, most NaCl/KCl/urea-treated Ag flakes still floated on top of the solution and Ag-HPUA electrodes experienced a minor resistance drop within 14 min, probably due to the limited capability of low-concentration Cl⁻ ions to remove the lubricant and sinter the Ag flakes.

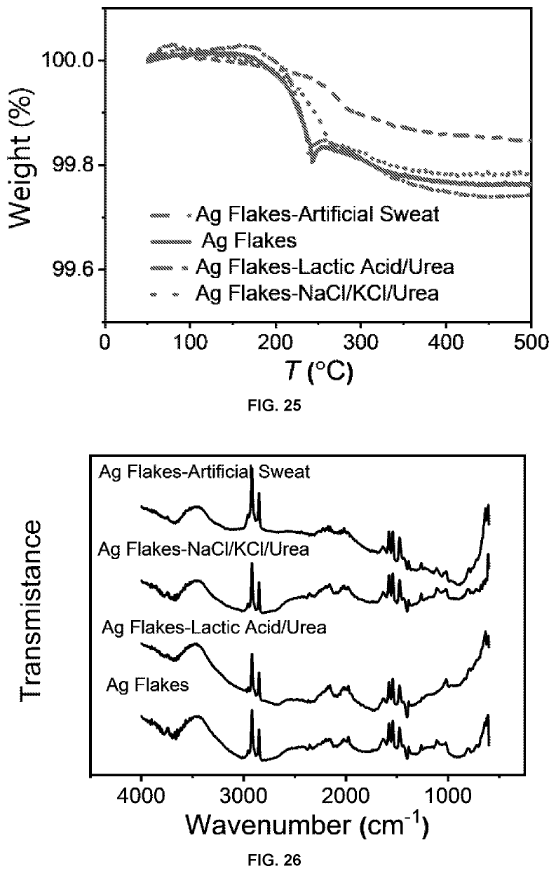

Synergistically, the combination of low-concentration lactic acid and Cl⁻ ions induces the enhanced aggregation of silver flakes and fast resistance drop of Ag-HPUA electrodes because of the augmented capability to remove lubricant surfactant and accelerate dissolution/redeposition of Ag. TGA was applied to detect the weight percentage of lubricant in Ag flakes. The result in FIG. 25 clearly shows that the remaining weight of artificial sweat-treated Ag flakes was 99.8% which is higher than that of pristine, lactic acid/urea and NaCl/KCl-treated Ag flakes, suggesting that the artificial sweat containing lactic acid and CI-ions is the most powerful solution to remove the lubricant. However, lubricant cannot be fully removed by artificial sweat. The FTIR result of Ag flakes treated with artificial sweat (FIG. 26) shows that the functional groups from the lubricant layer remained on the surface of the Ag flakes after reaction with artificial sweat. The de-protonated carboxylate bands at 1635 cm⁻¹ and 1577 cm⁻¹ were observed, which are attributed to v(COO—)_{asym} and v(COO—)_{sym}, respectively (Peterson, K. I. et al., J. Phys. Chem. C 2016, 120, 23268-23275), resulting from the lubricant layer on the surface of the Ag flakes. The removal of lubricant weakens the physical barrier and favors the reaction among Ag flakes, lactic acid, and Cl⁻ ions.

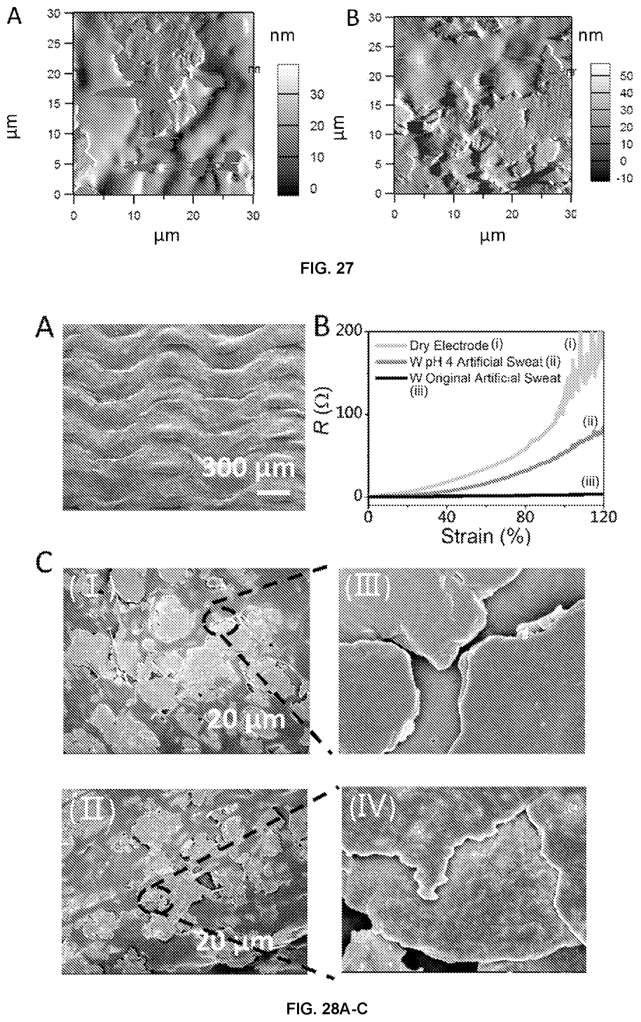

During the reaction between artificial sweat and Ag-HPUA electrodes, certainly, some Ag⁺ ions redeposit on the exposed Ag flakes though the dissolution of Ag is also taking place. In the conjunction area where the surface potential is higher than the other surface areas, the dissolved Ag⁺ ions may be more prone to redeposit in the conjunction area, resulting in the fusion of the adjacent Ag flakes and enhanced electrical conductivity (Lee, S. J. et al., Nanoscale 2014, 6, 11828-11834). This surface change is probably due to the reaction between the surface layer and artificial sweat, and accounts for the sweat-induced conductivity increment. The C-AFM comparison shows that the surface of the electrodes became more conductive after reaction with artificial sweat (FIG. 27 and FIG. 17I-J). These surface changes probably result from the reaction between the exposed Ag flakes and artificial sweat, and account for the sweat-induced conductivity increment of the printed electrode.

To verify the stability of the produced electron transfer traces, the electrode was immersed in pure water with magnetic stirring (for washing) after the reaction with artificial sweat. The resistance remained stable at around 0.65Ω with minor fluctuations coming from the magnetic stirring (FIG. 17K). This result means that once the resistance of Ag-HPUA electrodes is reduced by favorable sweats, for example with both low pH and high concentration of Cl⁻ ions, this conductivity enhancement can be maintained even when the subsequent component of sweat experiences a significant change. In real application scenarios, the component of human sweat changes with the sweat rate, for example, the pH at high sweating rates is higher than that at low sweating rates (Emrich, H. M. et al., Pediatr. Res. 1968, 2, 464-478). Reserving enough active species (lactic acid and Cl⁻) inside the porous textile substrate can be a way to mitigate this unstable sintering reaction caused by acidic and/or Cl⁻ deficient sweats. The textile was soaked in a 0.4% lactate solution and then dried to store lactic acid in the form of lactic anhydride before printing the electrodes on. When the textile comes into contact with water, the reserved lactic anhydride will dissolve immediately and take part in the sintering reaction. As shown in FIG. 17L, the lactic acid-soaked textile electrode showed a more significant resistance drop than the electrode printed on the bare textile soaked with pH 5.5 artificial sweat. The slower reaction than that of direct low pH artificial sweat-soaked samples is probably because of the dissolving process of the lactic anhydride (Zeng, Y.-X. et al., J. Nanomater. 2013, 2013, e270490).

### Example 9. Durability of Ag-HPUA Electrodes

The durability of Ag-HPUA electrodes was studied by following the sweat-enhanced conductivity protocol in Example 7.

Results and Discussion

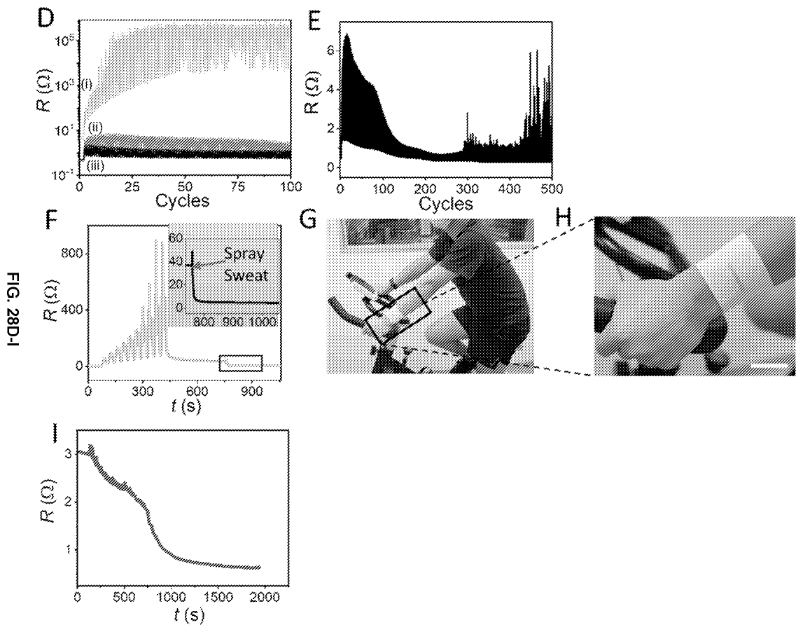

The durability of the electrodes to mechanical deformations caused by the wearer's daily activities, especially stretching, can guarantee wearable devices to work properly under and after the strain. Due to the flowing property and fast curing of the Ag-HPUA ink, the formed electrodes cannot penetrate deeply and fully cover the surface of each fiber. Instead, the cavities of the textile substrate are filled and fiber bundles are bonded by printed inks. This form factor is not favorable for stretchable textile electrodes because the strain from the deformed textile substrates will transmit fully to the printed electrode by the movement of the fibers (Jin, H. et al., Adv. Mater. 2017, 29, 1605848; and Wang, L. et al., Adv. Mater. 2020, 32, 1901971). However, the synthesized highly stretchable and elastic HPUA binder can resist the formation of obvious cracks on the Ag-HPUA electrodes upon 50% strain, as shown in FIG. 28A. The high capacity to resist the formation of cracking comes from the highly stretchable elastic HPUA binder. When the printed electrodes were soaked with artificial sweat and then stretched, both the initial resistance and the resistance increment under stretching are lower than that of the dry Ag-HPUA electrode (FIG. 28B). Also, a low pH is favorable for the sintering reaction under stretching (to 120%) as the resistances of pH 4 sweat and original artificial sweat (pH=2.7)-soaked electrodes increased from 0.57Ω to 82.5Ω and 0.36Ω to 3.5Ω, respectively.

During stretching in the presence of artificial sweat, the separation of Ag flakes and the sintering reaction take place simultaneously. Stretching makes Ag flakes inside the HPUA matrix slide with each other to accommodate the imparted strain and thus, the number of electrical conductive percolations is decreased, showing in the form of resistance increase. The reaction between artificial sweat and Ag-HPUA electrodes can create new electron transfer paths during the stretching and counteract stretching-induced conductivity loss. The SEM images of the dry and sweat-soaked electrodes under 50% stretching are shown in FIG. 28C(I)-(II), respectively, and FIG. 28C(III)-(IV) are the corresponding magnifications. Under stretching, more Ag flakes inside the Ag-HPUA electrodes are exposed and react with human sweat, making the surface of Ag flakes coarser than that of the dry electrode, which agrees well with the observations in non-stretched electrodes.

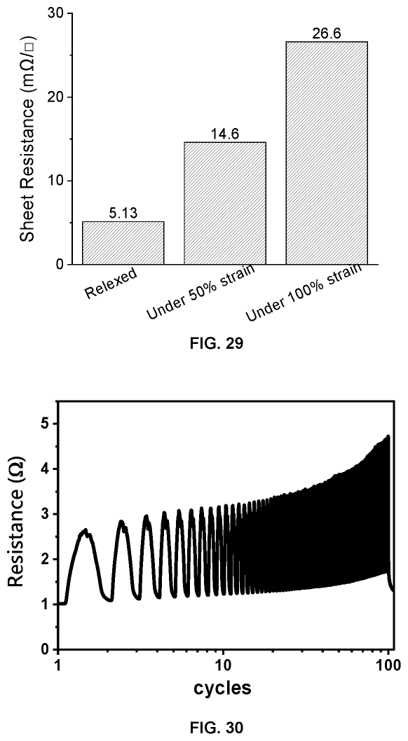

The sweat-induced sintering reaction also significantly increased the electrode's durability to cyclic tensile deformation which is super catastrophic in real application scenarios, as shown in FIG. 28D. Without sweat, the resistance of the printed electrodes increased to more than 40 kΩ at the strained state and 5 kΩ at the released state. In contrast, the pH 4 sweat enabled the electrode to have a much less resistance increment after 100 cycles of 30% stretching, staying at 2.4Ω at the strained state and 0.76Ω at the relaxed state. The original artificial sweat with pH 2.7 is more powerful to minimize the resistance increment caused by cycling stretching. The effect of sweat in reducing the stretching-induced resistance increase is more distinct in cyclic stretching than in single 120% stretching, resulting from the prolonged reaction-induced continuous generation of electron transfer paths. Both the resistance at the stretched state and the relaxed state kept dropping with continuous cycling stretching, which is opposite to previously reported printed stretchable Ag flakes-based electrodes (Jin, H. et al., Adv. Mater. 2017, 29, 1605848). The sheet resistance of the printed textile electrode after treatment by artificial solution was around 5.13 mΩ/□, 14.60 mΩ/□ under 50% stretching, and 26.6 mΩ/□ under 100% stretching, as shown in FIG. 29. The resistance increase after 100 cycles of 50% stretching was ΔR/R₀=1.86 (hysteresis), as shown in FIG. 30.

The stretchable HPUA binder can hold the conductive fillers together and the sintering reaction is responsible for creating new conductive networks, making sweat (pH 4)-soaked Ag-HPUA electrode maintain low resistance at both released status (0.26Ω) and stretched status (5Ω) even after 500 cycles of 30% stretching (FIG. 28E). The acidic sweat also can repair the conductivity loss of electrodes caused by stretching. As shown in FIG. 28F, the resistance of the dry Ag-HPUA electrode increased from 2.62Ω to 36.7Ω after 10 cycles of 30% stretching and then the spraying of pH 4 artificial sweat reduced the resistance to less than 5Ω within 2 min, further showing the ability of sweat in reducing the resistance of stretchable Ag-HPUA electrodes.

Even after drying, the artificial sweat-soaked electrode still maintained low initial resistance and high stretchability. The single stretching and cycling stretching compared with the original Ag-HPUA electrode are shown in FIG. 31A and FIG. 31B, respectively. After soaking in artificial sweat (pH=2.7) and drying, the Ag-HPUA electrode exhibited much higher durability to mechanical deformation.

### Example 10. In-Vivo Study of Ag-HPUA Electrodes

In-Vivo Study

The in-vivo study was carried out by monitoring the resistance change of Ag-HPUA electrodes wrapped on the subject's arm when the subject was doing stationary cycling to initiate the sweating. The test was conducted under the approved IRB-2017-08-038-02.

Release of Ag⁺ into Sweat After soaking the electrode inside artificial sweat solution, the concentration of released Ag⁺ was determined by Inductively Coupled Plasma Mass Spectrometry (ICP-MS, Elan-DRC-e, Perkin Elmer).

Results and Discussion

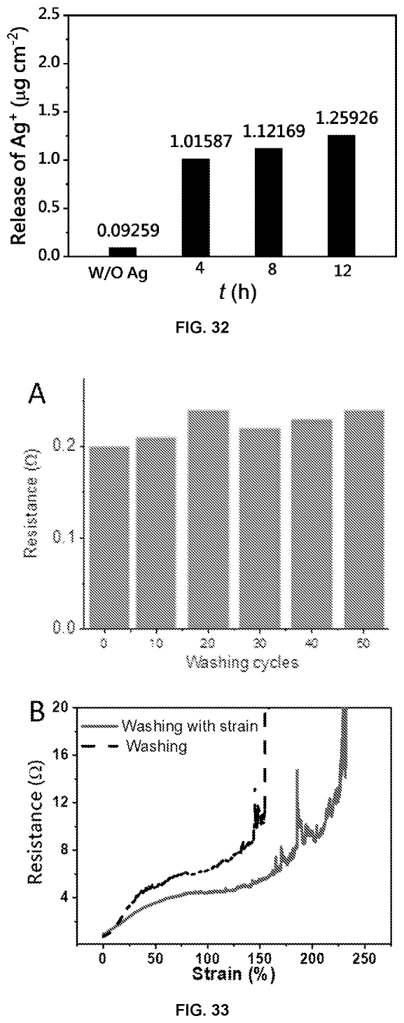

The in-vivo study results are shown in FIG. 28G-H. The initial resistance was around 3.02Ω, and dropped to 0.62Ω after 27 min of cycling, demonstrating the practical capability of sweat to reduce the resistance of Ag-HPUA electrodes. For real application scenarios, the amount of released Ag⁺ into the sweat is crucial to evaluate the toxicity of Ag-HPUA electrodes because the Ag⁺ is the most detrimental form of Ag element to human skin. As shown in FIG. 32, the release of Ag⁺ into the sweat was around 1.26 μg/cm² area of Ag-HPUA electrodes after 12 h, which is comparable with commercialized Ag nanoparticle-coated anti-bacterial textiles (Wang, L. et al., Adv. Mater. 2020, 32, 1901971). Most Ag flakes are wrapped by HPUA, which would significantly impede the release of Ag⁺ into the sweat though the electrodes contain a high proportion of Ag flakes.

### Example 11. Washing Process on Ag-SEBS Electrodes

Washing Process

The washing process was performed by soaking a piece of textile with printed Ag-SEBS electrode on in 500 ml detergent/water (1 g/500 ml) solution with a stir bar at a speed of 500 rpm. The detergent (Top Concentrated Liquid Detergent) was purchased from Lion. The resistance of the electrode was monitored after every 10 cycles of washing and in total, 50 cycles of washing were finished.

Additional Procedure to Increase Stretchability of Electrodes

The additional procedure for applying the strain was done before encapsulating the electrode. During soaking of the electrode in the artificial sweat solution, the strain was utilized to further increase the stretchability of the electrode.

Results and Discussion

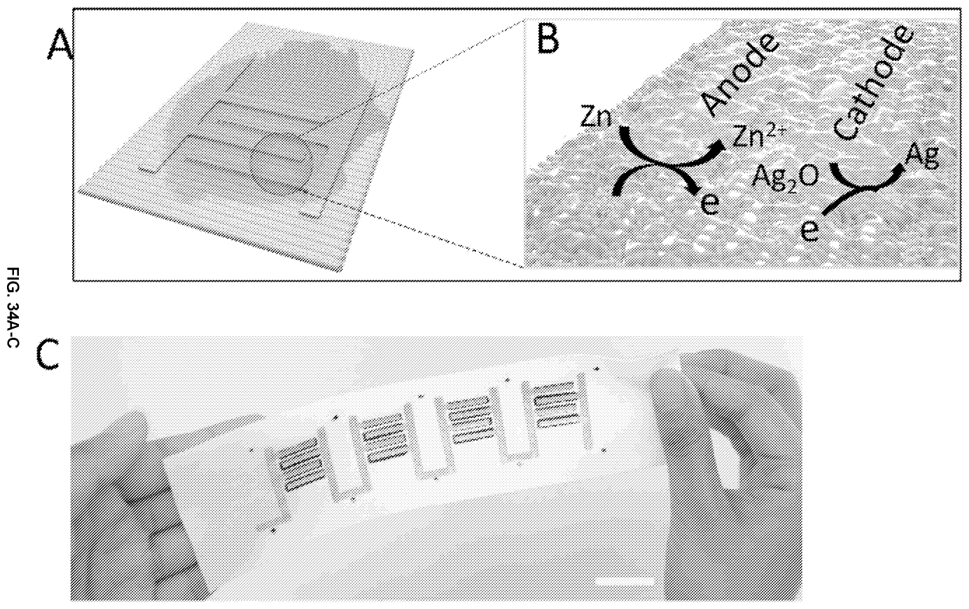

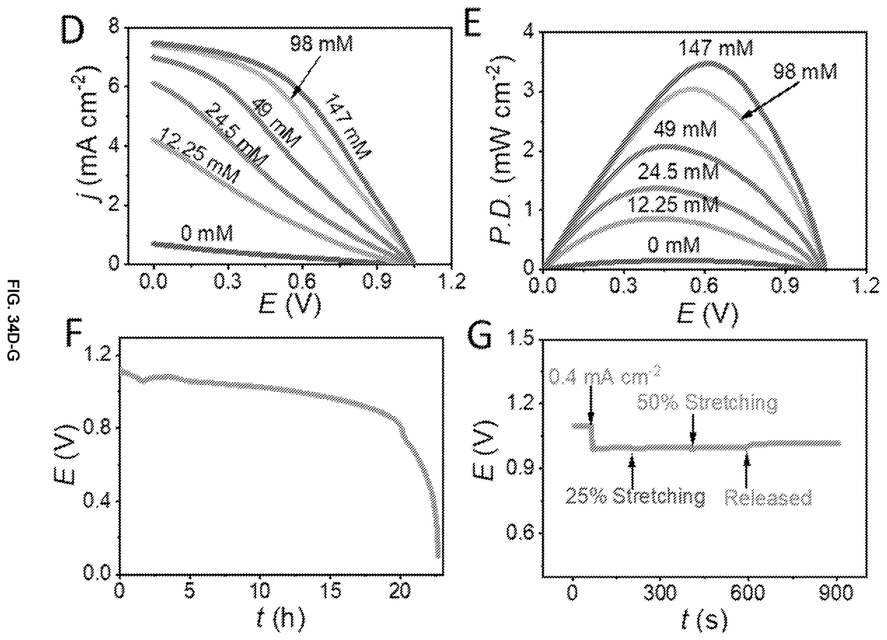

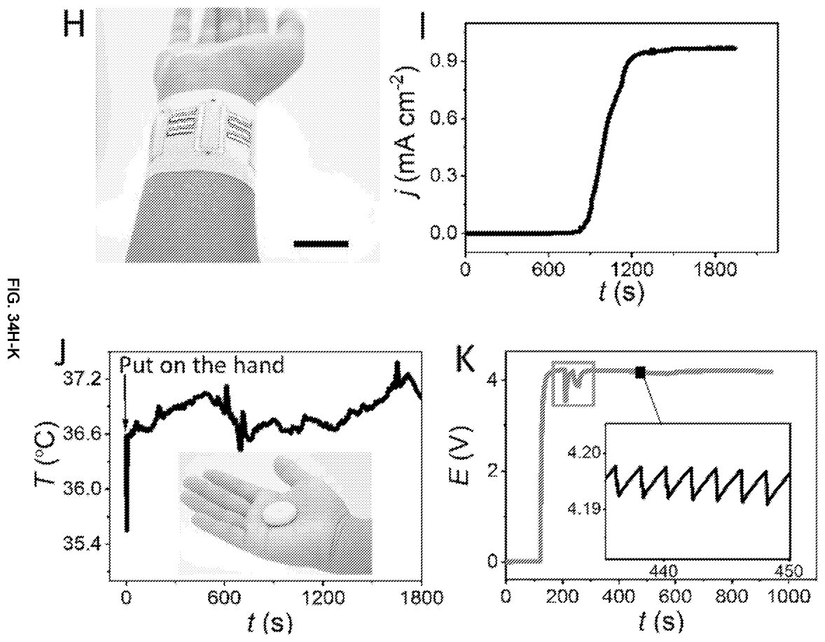

The resistance change of the encapsulated electrode during washing is shown in FIG. 33A. cycles of washing did not significantly increase the resistance of the printed electrode. The utilization of strain during the soaking process can increase the stretchability of the printed electrode on textile, as shown in FIG. 33B. The resistance increment upon stretching was less when the textile electrode was stretched during the soaking. Therefore, this additional procedure can enhance the stretchability of our electrodes.

### Example 12. Printing of Stretchable Zn—Ag₂O Sweat Battery

The capability of sweat to enhance the conductivity of Ag-HPUA electrodes provides more guidance into the design of the wearable electronics that need to be in intimate contact with human skin as sweat is one of the most liable biofluids secreted by the human body. To demonstrate the application of sweat sintering reaction, we designed the first example of a textile-based stretchable Zn—Ag₂O sweat battery that utilizes human sweat as the electrolyte and Ag-HPUA electrodes as stretchable current collectors to provide energy for the wearable electronics.

Printing of Stretchable Zn—Ag₂O Sweat Battery

Zn flake powder and Ag₂O powder were mixed with carbon black (CB) at the weight ratios of 90:10 and 95:5, respectively, by mortar grinding for 10 min. The Zn inks and Ag₂O inks were formulated by mixing Zn/CB and Ag₂O/CB with the HPUA binder in the ratio of 1:2 and 1:1.2, respectively, and then shaking for 10 min. The two formulated inks were printed on the textile substrate in an interdigit shape in a lab-made black box and cured at ambient condition for 10 min without any heating or specific UV lightning. Then, Ag-HPUA inks were printed on top of the two electrodes as the current collector (FIG. 34A-C), and cured in lab ambient environment.

Results and Discussion

The structure of the stretchable sweat-activated battery is shown in FIG. 34A. The printed Zn electrode was selected as the anode and Ag₂O as the cathode, respectively. Besides serving as the sweat absorbent and separator, the porous textile substrate also enables the high loading of electrode inks, as shown in FIG. 34B. In the presence of human sweat, electrons are generated on the anode from Zn flakes and then transferred to the cathode through external loading to reduce Ag₂O to Ag. Compared with reported sweat-activated batteries (von Goetz, N. et al., Environ. Sci. Technol. 2013, 47, 9979-9987), this scalable and pattern-designable printing technology facilitates the massive and cheap manufacturing of sweat-activated batteries, as shown in FIG. 34C.

### Example 13. Electrochemical Characterization of Stretchable Zn—Ag₂O Sweat Battery

Electrochemical Characterization of Stretchable Zn—Ag₂O Sweat Battery

The artificial sweats (pH=4) with different NaCl/KCl concentrations were used as the electrolytes for in-vivo studies. The polarization curves were tested by an electrochemical potentiostat (Autolab) with a scan rate of 5 mV/s from open circuit potential to 0 V. The discharging curve was obtained from a battery-testing instrument (Newar) at a current density of 0.2 mA/cm². The in-vivo energy generation was tested by anchoring the printed battery with a series-connected 1 KΩ resistor on a subject's arm and monitoring the current of the circuit continuously during stationary cycling. The application demonstration of the battery was performed by powering a wireless epidermal temperature sensor (MMC-T201-1, Miaomiaoce, China) with a 5.6 mF capacitor to modulate the energy generated by the 4 series-connected sweat batteries on the subject's arm. The voltage of the capacitor was measured by the DAQ 6510 multimeter and the temperature sensor sent in-vivo data continuously to the app in smartphone per 2 s.

Results and Discussion

The linear sweep voltammetry (LSV) curves and power curves of the stretchable sweat-activated battery using artificial sweat electrolyte with increased concentration of NaCl are shown in FIG. 34D and FIG. 34E, respectively. The power density of the printed batteries was boosted from 0.149 to 3.47 mW/cm² when the concentration of NaCl increased from 0 mM to 147 mM. At 0.2 mA/cm² discharging current (FIG. 34F), the capacity of the battery was around 4 mAh/cm², which is comparable to the reported stretchable Li-ion battery (Mackanic, D. G. et al., Nat. Commun. 2019, 10, 5384). In the presence of sweat, the new conductive networks can be formed on the Ag-HPUA current collectors by the reaction between Ag flakes and sweat, making the sweat batteries work properly under external strain. As shown in FIG. 34G, 25% and 50% stretching caused a minor change to the voltage of the battery when it was discharged at a current density of 0.4 mA/cm².

The durability of mechanical deformation enables the printed batteries to generate energy properly on the subject's forearm during the secretion of sweat (FIG. 34H). The current density of a printed battery with 1 kΩ external loading was increased from 0 to 0.97 mA/cm² after 16 min of exercise, and maintained at this level afterward (FIG. 34I), demonstrating the practical workability of the human sweat to serve as the biocompatible electrolyte for Zn—Ag₂O batteries.

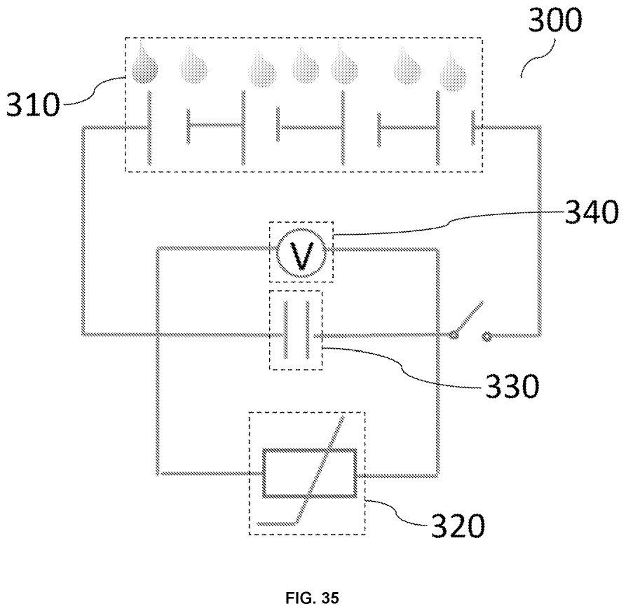

As the Covid-19 is plaguing the world, the continuous monitoring of the body temperature is pretty valuable in the prevention of infection. Printed stretchable sweat batteries can serve as the power source to power a commercial wireless temperature sensor to monitor the temperature on the hand of the subject, and to send the data to a smartphone, as shown in FIG. 35 and FIG. 34G. As depicted in FIG. 35, there is a circuit 300 that includes 4 series-connected sweat-based Zn—Ag₂O batteries 310, wearable wireless temperature sensor 320, a 5.6 mF capacitor 330, and a voltmeter 340. A 5.6 mF capacitor was utilized to buffer the energy generated by batteries and the voltage change of the capacitor as shown in FIG. 34K. The 4 series-connected batteries can charge the capacitor to 4.17 V in 40 s, and then the sensor started to send high-current pulse signals to connect the smartphone and send in-vivo temperature data. The batteries can timely compensate the consumed energy in the capacitor in both the connecting period and data sending period. Especially in the connecting period, the frequency of pulse sent by the wireless circuit was much higher but our batteries can still supply enough energy for the sensor to work properly.

1. A flexible textile-based silver electrode, comprising:
a flexible textile substrate having a surface; and
a polymeric silver electrode wire attached to the surface of the flexible textile substrate, the electrode wire comprising:
an elastomeric material; and
silver flakes homogeneously distributed throughout the elastomeric material, wherein:
the fraction of Ag⁰ in the silver flakes is from 89 to 95% relative to Ag⁺; and
the hysteresis (ΔR/R₀) of the flexible textile-based silver electrode following 100 cycles of being elongated by 50% of its original dimension is from 1.1 to 2.

2. The flexible textile-based silver electrode according to claim 1, wherein the elastomeric material is selected from one or more of a silicone rubber, a styrenic elastomer, and a polyurethane-based elastomer.

3. The flexible textile-based silver electrode according to claim 2, wherein the elastomeric material is a hydrophilic polyurethane acrylate elastomer.

4. The flexible textile-based silver electrode according to claim 2, wherein the elastomeric material is cured.

5. The flexible textile-based silver electrode according to claim 2, wherein the uncured elastomeric material has a formula I: 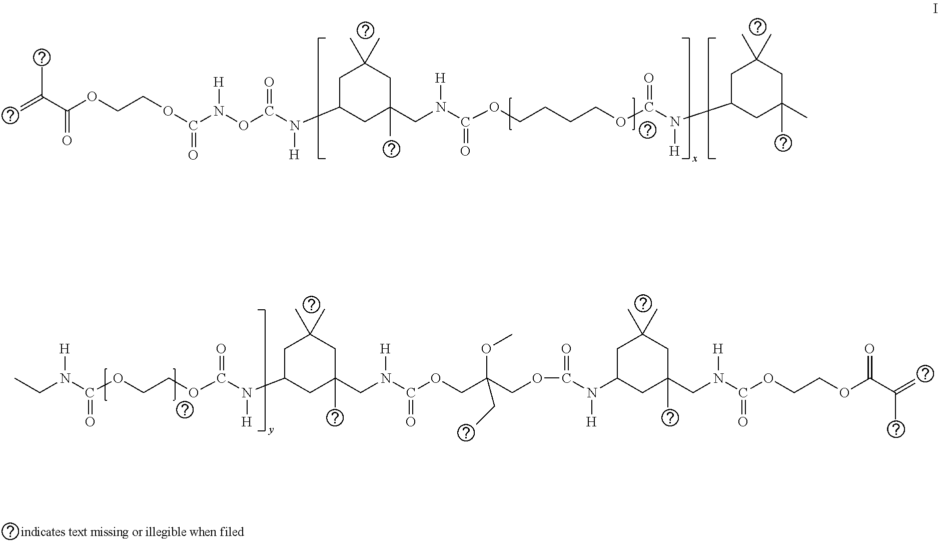
where n, x and y represent repeating units, and the cured elastomeric material, when present, is the acrylate-polymerised version thereof.

6. The flexible textile-based silver electrode according to claim 1, wherein one or more of the following apply:
(ci) the weight to weight ratio of the silver flakes to elastomeric material is from 1:0.1 to 0.1:1;
(cii) the resistance of the flexible textile-based silver electrode in a relaxed state is from 0.1 to 1.5Ω; and
(ciii) the resistance of the flexible textile-based silver electrode does not exceed 7Ω when the flexible textile-based silver electrode is subjected to 500 cycles of being elongated by 30% of its original dimension in any direction.

7. The flexible textile-based silver electrode according to claim 1, wherein one or more of the following apply:
(ai) a surface of the polymeric silver electrode wire that is not in direct contact with the textile substrate is coated by a non-silver containing elastomeric material;
(aii) flexible textile substrate comprises a plurality of bundles of yarn on the surface of the textile substrate, where the plurality of bundles of yarn in contact with the polymeric silver electrode wire extend partly into the polymeric silver electrode wire; and
(aiii) the elastomeric material has a water contact angle of from 10 to 25°, after contact with a water droplet for 80 minutes.

8. A sweat-activated battery comprising:
a textile substrate;
a cathode comprising a cathode sweat-activated active material and a first elastomeric material on the textile substrate;
an anode comprising a sweat-activated active material and a second elastomeric material on the textile substrate; and
a current collector formed from a polymeric silver electrode wire attached to the surface of the flexible textile substrate, the electrode wire comprising:
a third elastomeric material; and
silver flakes homogeneously distributed throughout the third elastomeric material, wherein
a current is produced by the battery when the battery is placed into an environment including an aqueous composition comprising an inorganic chloride salt and an organic acid.

9. The battery according to claim 8, wherein the anode sweat-activated active material is selected from one or more of zinc powder (particles/flakes) and carbon particles.

10. The battery according to claim 8, wherein the weight to weight ratio of the anode sweat-activated active material to elastomeric material is from 1:1 to 1:3.

11. The battery according to claim 8, wherein the cathode sweat-activated active material is selected from one or more of Ag₂O powder and carbon.

12. The battery according to claim 8, wherein the weight to weight ratio of the cathode sweat-activated active material to elastomeric material is from 1:1 to 1:1.5.

13. The battery according to claim 8, wherein each of the first to third elastomeric materials are independently selected from one or more of a silicone rubber, a styrenic elastomer, and a polyurethane-based elastomer.

14. The battery according to claim 13, wherein each of the first to third elastomeric materials are a hydrophilic polyurethane acrylate elastomer.

15. The battery according to claim 13, wherein each of the first to third the elastomeric materials are cured.

16. The battery according to claim 13, wherein for each of the first to third elastomeric materials the uncured elastomeric material has a formula I: 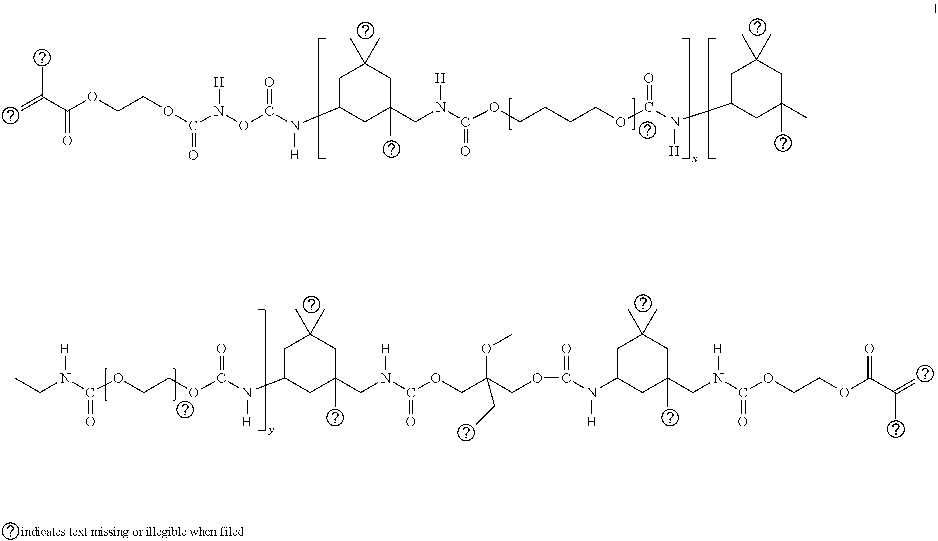
where n, x and y represent repeating units, and the cured elastomeric material, when present, is the acrylate-polymerised version thereof.

17. The battery according to claim 8, wherein the weight to weight ratio of the silver flakes to the third elastomeric material is from 1:0.1 to 0.1:1.

18. The battery according to claim 8, wherein one or more of the following apply:
(ai) a surface of the polymeric silver electrode wire that is not in direct contact with the textile substrate is coated by a non-silver containing elastomeric material;
(aii) flexible textile substrate comprises a plurality of bundles of yarn on the surface of the textile substrate, where at the plurality of bundles of yarn in contact with the polymeric silver electrode wire extend partly into the polymeric silver electrode wire; and
(aiii) the elastomeric material has a water contact angle of from 10 to 25°.

19. A device comprising:
one or more sweat-activated batteries according to claim 8; and
a capacitor.

20. A method of making a flexible textile-based silver electrode as described in claim 1, comprising the steps of:
(a) providing a composite material comprising:
a flexible textile substrate having a surface; and
a polymeric silver electrode wire attached to the surface of the flexible textile substrate, the electrode wire comprising:
an elastomeric material; and
silver flakes homogeneously distributed throughout the elastomeric material; and
(b) bringing the composite material into contact with an aqueous solution comprising a non-toxic chloride salt and an organic acid for a period of time to form the flexible textile-based silver electrode.

21. The method according to claim 20, wherein the pH of the aqueous solution is from 2.5 to 4.0.

22. The method according to claim 20, wherein step (b) of claim 20 is conducted in a washing machine.

23. The method according to claim 20, wherein the aqueous solution comprises from 0.1 to 1 wt/v % of an inorganic chloride salt and from 0.05 to 0.5 wt/v % of an organic acid.

24. The method according to claim 20, wherein one or both of the following apply:
the non-toxic chloride salt is selected from one or more of the group consisting of CaCl₂), MgCl₂ and, more particularly, NaCl and KCl; and
(ii) the organic acid is selected from one or more of the group consisting of citric acid, acetic acid, tartaric acid, malic acid and, more particularly, lactic acid.

25. The method according to claim 20, wherein the period of time in step (b) of claim 20 is at least 30 seconds to 24 hours.

26. The method according to claim 20, wherein the flexible textile substrate is loaded with an organic acid.
